(19) United States
(12) Patent Application Publication
(10) Pub. No.: US 2024/0431089 A1
(43) Pub. Date: Dec. 26, 2024

(54) MEMORY DEVICE

(71) Applicant: Taiwan Semiconductor Manufacturing Company, Ltd., Hsinchu (TW)

(72) Inventor: Jhon-Jhy LIAW, Zhudong Township (TW)

(73) Assignee: Taiwan Semiconductor Manufacturing Company, Ltd., Hsinchu (TW)

(21) Appl. No.: 18/338,984

(22) Filed: Jun. 21, 2023

(51) Int. Cl. H10B 10/00

(52) U.S. Cl. CPC H10B 10/125

(57) ABSTRACT

A memory device includes a static random access memory (SRAM) cell including a first inverter and a second inverter. The first inverter has a first pull-down transistor and a first pull-up transistor. The second inverter has a second pull-down transistor and a second pull-up transistor. The first inverter and the second inverter are cross-coupled to each other. Each of the first pull-down transistor, the first pull-up transistor, the second pull-down transistor, and the second pull-up transistor includes active channel layers vertically stacked. A number of the active channel layers of the first pull-up transistor is less than a number of the active channel layers of the first pull-down transistor or the second pull-down transistor.

### BACKGROUND

The semiconductor integrated circuit (IC) industry has experienced exponential growth. Technological advances in IC materials and design have produced generations of ICs where each generation has smaller and more complex circuits than the previous generation. In the course of IC evolution, functional density (i.e., the number of interconnected devices per chip area) has generally increased while geometric size (i.e., the smallest component (or line) that can be created using a fabrication process) has decreased. This scaling-down process generally provides benefits by increasing production efficiency and lowering associated costs. Such scaling down has also increased the complexity of processing and manufacturing ICs and, for these advancements to be realized, similar developments in IC processing and manufacturing are needed.

As integrated circuit (IC) technologies progress towards smaller technology nodes, gate-all-around (GAA) transistors have been incorporated into memory devices (including, for example, static random-access memory, or SRAM, cells) to reduce chip footprint while maintaining reasonable processing margins.

However, although existing technologies for fabricating memory array including GAA transistors have been generally adequate for their intended purposes, they have not been entirely satisfactory in all respects.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 is a fragmentary diagrammatic top view of an integrated circuit (IC) chip, in portion or entirety, in accordance with some embodiments of the present disclosure.

FIGS. 2 and 3 are circuit diagrams of an SRAM circuit that can be implemented in an SRAM cell of an array in the memory region of FIG. 1, in accordance with some alternative embodiments of the present disclosure.

FIG. 4 is a perspective view of a GAA transistor in an array of SRAM cells, in accordance with some embodiments of the present disclosure.

FIG. 5A is a top view (or a layout) of an SRAM cell that can be one embodiment of the SRAM cells implemented in the array, in accordance with some embodiments of the present disclosure.

FIG. 5B is an X-Z cross-sectional view of the SRAM cell along a line A-A′ in FIG. 5A, in accordance with some embodiments of the present disclosure.

FIG. 5C is a Y-Z cross-sectional view of the SRAM cell along a line B-B′ in FIG. 5A, in accordance with some embodiments of the present disclosure.

FIG. 5D is a Y-Z cross-sectional view of the SRAM cell along a line C-C′ in FIG. 5A, in accordance with some embodiments of the present disclosure.

FIGS. 6A and 6B are Y-Z cross-sectional views of a first alternative SRAM cell along the lines B-B′ and C-C′ in FIG. 5A, respectively, in accordance with some embodiments of the present disclosure.

FIGS. 7A and 7B are Y-Z cross-sectional views of a second alternative SRAM cell along the lines B-B′ and C-C′ in FIG. 5A, respectively, in accordance with some embodiments of the present disclosure.

FIGS. 8A and 8B are Y-Z cross-sectional views of a third alternative SRAM cell along the lines B-B′ and C-C′ in FIG. 5A, respectively, in accordance with some embodiments of the present disclosure.

FIG. 9A is an X-Z cross-sectional views of a fourth alternative SRAM cell along the line A-A′ in FIG. 5A, in accordance with some embodiments of the present disclosure.

FIGS. 9B and 9C are Y-Z cross-sectional views of the fourth alternative SRAM cell along the lines B-B′ and C-C′ in FIG. 5A, respectively, in accordance with some embodiments of the present disclosure.

FIGS. 10A and 10B are Y-Z cross-sectional views of a fifth alternative SRAM cell along the lines B-B′ and C-C′ in FIG. 5A, respectively, in accordance with some embodiments of the present disclosure.

FIGS. 11A and 11B are Y-Z cross-sectional views of a sixth alternative SRAM cell along the lines B-B′ and C-C′ in FIG. 5A, respectively, in accordance with some embodiments of the present disclosure.

FIGS. 12A and 12B are Y-Z cross-sectional views of a seventh alternative SRAM cell along the lines B-B′ and C-C′ in FIG. 5A, respectively, in accordance with some embodiments of the present disclosure.

FIGS. 13A, 13B, 13C, 13D, 13E, 13F, 13G, and 13H are cross-sectional views of a device at various fabrication stages, in accordance with some embodiments of the present disclosure.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

The present disclosure is generally related to memory structures, and more particularly to an array of static random-access memory (SRAM) cells having field-effect transistors (FETs), such as three-dimensional gate-all-around (GAA) transistors, in an integrated circuit (IC) structure. Generally, a GAA transistor may include a plurality of vertically stacked sheets (e.g., nanosheets), wires (e.g., nanowires), or rods (e.g., nanorods) in a channel region of the transistor, thereby allowing better gate control, lowered leakage current, and improved scaling capability for various IC applications.

The gate-all-around (GAA) transistor structures may be patterned by any suitable method. For example, the structures may be patterned using one or more photolithography processes, including double-patterning or multi-patterning processes. Generally, double-patterning or multi-patterning processes combine photolithography and self-aligned processes, allowing patterns to be created that have, for example, pitches smaller than what is otherwise obtainable using a single, direct photolithography process. For example, in one embodiment, a sacrificial layer is formed over a substrate and patterned using a photolithography process. Spacers are formed alongside the patterned sacrificial layer using a self-aligned process. The sacrificial layer is then removed, and the remaining spacers may then be used to pattern the GAA structure.

Embodiments of the present disclosure offer advantages over the existing art, though it should be understood that other embodiments may offer different advantages, not all advantages are necessarily discussed herein, and no particular advantage is required for all embodiments. For example, embodiments discussed herein include an array of SRAM cells, in which the SRAM cells have pull-up transistors with less channel layers than pull-down transistors and pass-gate transistors, such that improve cell performance. The details of the present disclosure are described below in conjunction with the accompanying drawings, which illustrate the layout and structure of circuit cells, according to some embodiments.

The various aspects of the present disclosure will now be described in more detail with reference to the figures. For avoidance of doubts, an X-direction, a Y-direction, and a Z-direction in the figures are perpendicular to one another and are used consistently. Throughout the present disclosure, like reference numerals denote like features unless otherwise excepted.

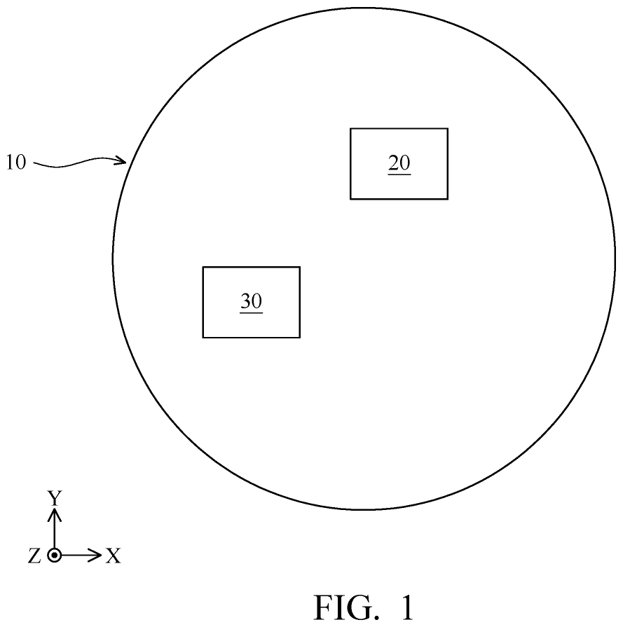

FIG. 1 is a fragmentary diagrammatic top view of an integrated circuit (IC) chip 10, in portion or entirety, in accordance with some embodiments of the present disclosure. IC chip 10 may include various passive microelectronic devices and active microelectronic devices, such as resistors, capacitors, inductors, diodes, p-type field effect transistors (PFETs), n-type field effect transistors (NFETs), metal-oxide semiconductor field effect transistors (MOSFETs), CMOS transistors, bipolar junction transistors (BJTs), laterally diffused MOS (LDMOS) transistors, high voltage transistors, high-frequency transistors, another suitable component, or a combination thereof. The various microelectronic devices can be configured to provide IC chip 10 with functionally distinct regions, such as a core region (also referred to as a logic region), a memory region (e.g., a static random access memory (SRAM) region), an analog region, a peripheral region (also referred to as an input/output (I/O) region), a dummy region, and/or other suitable region. In some embodiments, IC chip 10 includes a memory region 20 and a logic region 30. Memory region 20 can include an array of memory cells, each of which includes transistors and interconnection structures (also referred to as routing structures) that combine to provide a storage device and/or a storage function, such as a flip flop, a latch, another suitable memory device, or a combination thereof. In some embodiments, memory region 20 is configured with static random-access memory (SRAM) cells, dynamic random-access memory (DRAM) cells, non-volatile random-access memory (NVRAM) cells, flash memory cells, other suitable memory cells, or a combination thereof. Logic region 30 can include an array of standard cells, each of which includes transistors and interconnection structures that combine to provide a logic device and/or a logic function, such as an inverter, an AND gate, an NAND gate, an OR gate, an NOR gate, a NOT gate, an XOR gate, an XNOR gate, another suitable logic device, or a combination thereof. FIG. 1 has been simplified for the sake of clarity to better understand the inventive concepts of the present disclosure. Additional features can be added in IC chip 10, and some of the features described herein can be replaced, modified, or eliminated in other embodiments of IC chip 10.

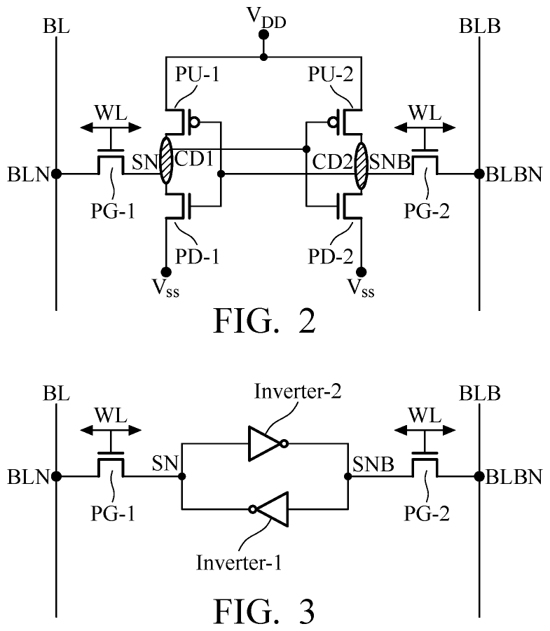

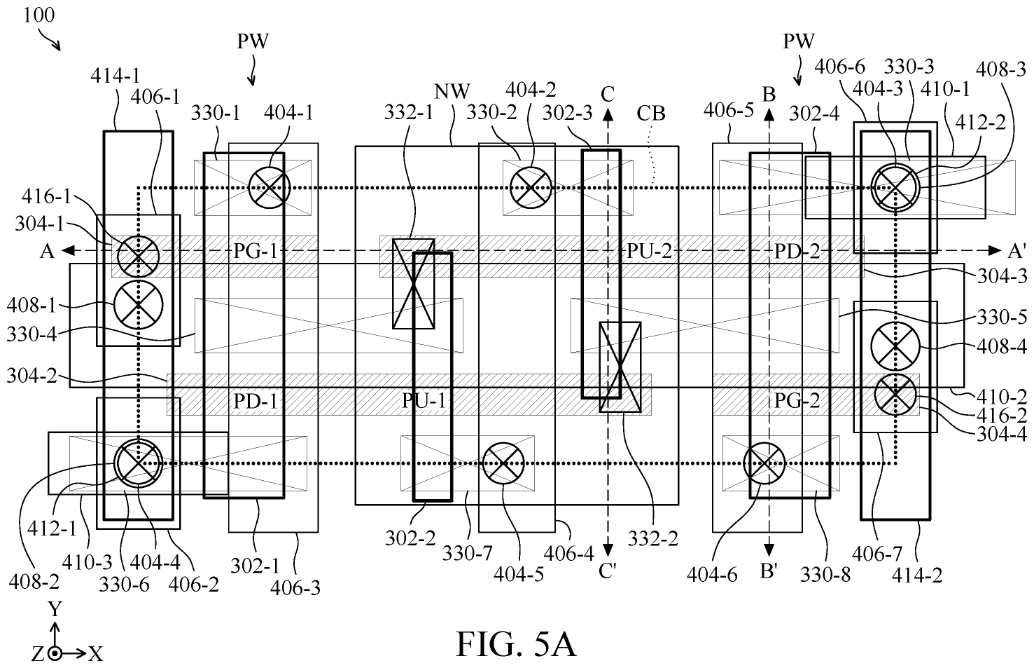

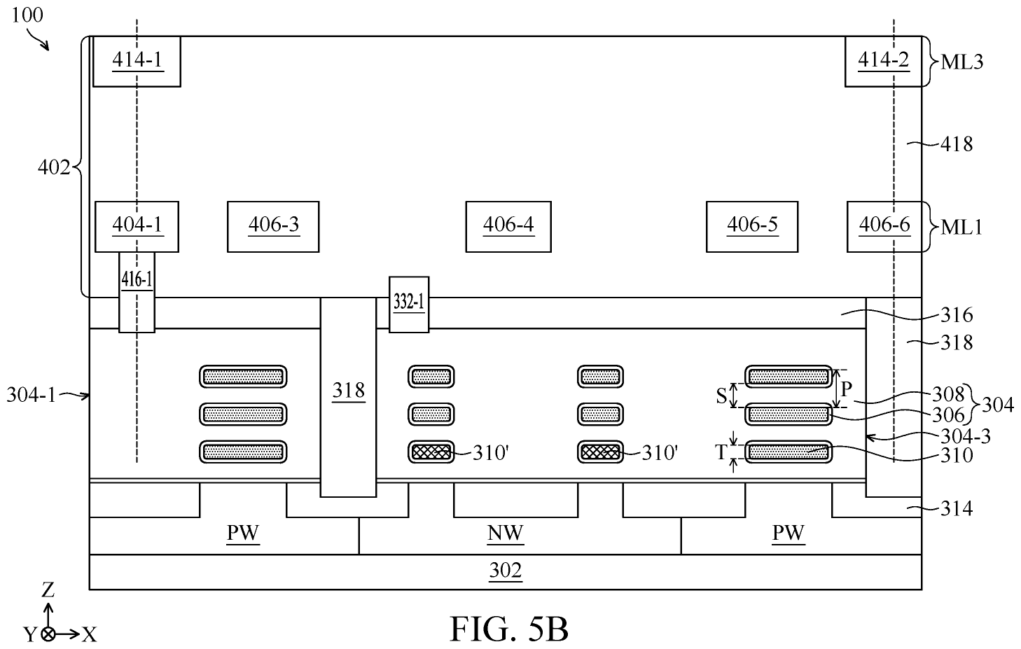

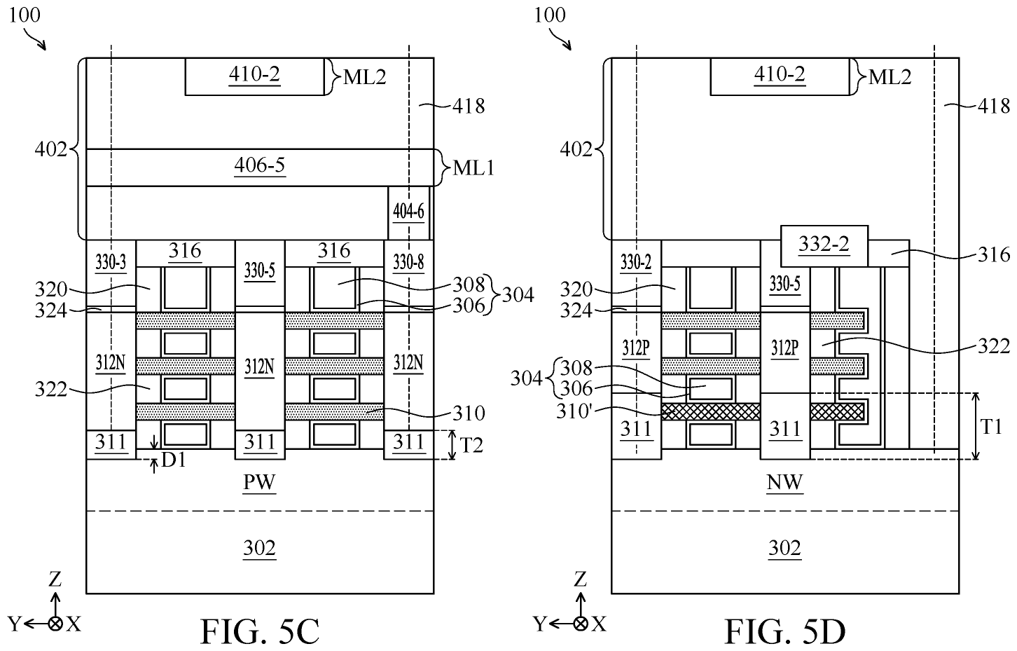

FIGS. 2 and 3 are circuit diagrams of an SRAM circuit that can be implemented in an SRAM cell (e.g., an SRAM cell 100 in FIG. 2) of an array in the memory region 20 of FIG. 1, in accordance with some alternative embodiments of the present disclosure. The circuit diagram of SRAM cell is merely exemplary, and in some embodiments, each of SRAM cells (e.g., SRAM cells 100 and 100A to 100G in FIGS. 5A to 12B) in the array is configured with an SRAM circuit similar to the SRAM cell shown in FIG. 2 and FIG. 3. For example, each of SRAM cells has a storage portion that includes a cross-coupled pair of inverters (also referred to as a latch), such as an Inverter-1 and an Inverter-2. Inverter-1 includes pull-up transistor PU-1 and pull-down transistor PD-1, and Inverter-2 includes pull-up transistor PU-2 and pull-down transistor PD-2. Pass-gate transistor PG-1 is connected to an output of Inverter-1 and an input of Inverter-2, and pass-gate transistor PG-2 is connected to an output of Inverter-2 and an input of Inverter-1. In operation, pass-gate transistor PG-1 and pass-gate transistor PG-2 provide access to the storage portion of their respective SRAM cell (i.e., Inverter-1 and Inverter-2) and can also be referred to as access transistors of their respective SRAM cell. Each of SRAM cells (e.g., the SRAM cells 100 and 100A to 101K in FIGS. 5A to 12B) is connected to and powered through a first power supply voltage, such as a positive power supply voltage, and a second power supply voltage, such as a ground voltage or a reference voltage (which can be an electrical ground). A gate of pull-up transistor PU-1 interposes a source, which is electrically coupled to the first power supply voltage via a voltage node (or voltage source) VDD, and a first common drain (CD1) (i.e., a drain of pull-up transistor PU-1 and a drain of pull-down transistor PD-1). A gate of pull-down transistor PD-1 interposes a source, which is electrically coupled to the second power supply voltage via a voltage node (or voltage source) VSS, and the first common drain. A gate of pull-up transistor PU-2 interposes a source, which is electrically coupled to the first power supply voltage via voltage node VDD, and a second common drain (CD-2) (i.e., a drain of pull-up transistor PU-2 and a drain of pull-down transistor PD-2). A gate of pull-down transistor PD-2 interposes a source, which is electrically coupled to the second power supply voltage via voltage node VSS, and the second common drain. The first common drain provides a storage node SN that stores data in true form, and the second common drain provides a storage node SNB that stores data in complementary form, or vice versa, in some embodiments. The gate of pull-up transistor PU1 and the gate of pull-down transistor PD-1 are coupled together and to the second common drain SD2, and the gate of pull-up transistor PU-2 and the gate of pull-down transistor PD-2 are coupled together and to the first common drain SD1. A gate of pass-gate transistor PG-1 interposes a drain connected to a bit line node BLN, which is electrically coupled to a bit line BL, and a source, which is electrically coupled to the first common drain SD1. A gate of pass-gate transistor PG-2 interposes a drain connected to a complementary bit line node BLBN, which is electrically coupled to a complementary bit line BLB, and a source, which is electrically coupled to the second common drain SD2. Gates of pass-gate transistors PG-1, PG-2 are connected to and controlled by a word line WL, which allows selection of a respective SRAM cell, such as the SRAM cell 100, for reading and/or writing. In some embodiments, pass-gate transistors PG-1, PG-2 provide access to storage nodes SN, SNB, respectively, each of which can store a bit (e.g., a logical 0 or a logical 1), during read operations and/or write operations. For example, pass-gate transistors PG-1, PG-2 couple storage nodes SN, SNB, respectively, to bit line BL and bit line bar BLB in response to voltage applied to gates of pass-gate transistors PG-1, PG-2 by word line WL. In some embodiments, SRAM cells are single-port SRAMs. In some embodiments, SRAM cells are configured as multi-port SRAMs, such as dual-port SRAMs, and/or with more or less transistors than depicted, such as 8T SRAMs. FIG. 2 and FIG. 3 have been simplified for the sake of clarity to better understand the inventive concepts of the present disclosure. Additional features can be added in the SRAM circuits of FIG. 2 and FIG. 3, and some of the features described herein can be replaced, modified, or eliminated in other embodiments of the SRAM circuits of FIG. 2 and FIG. 3.

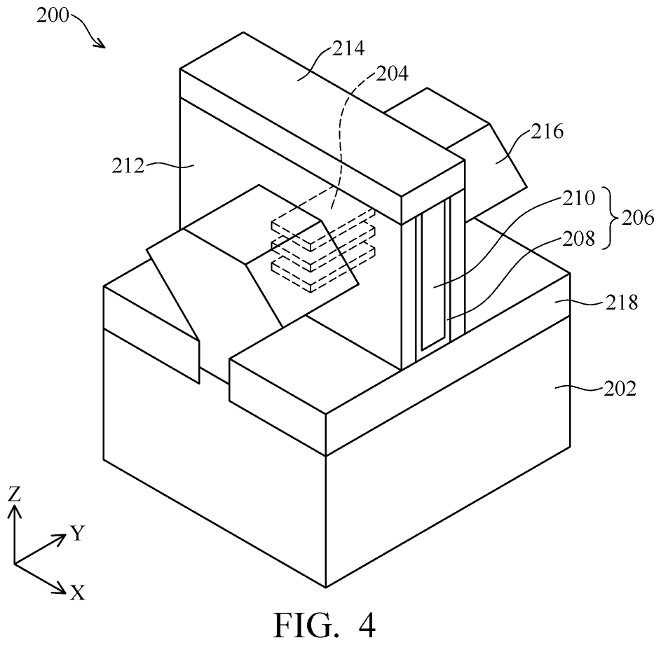

Each of the SRAM cells discussed above is constructed by transistors. The transistors may be planar transistors, fin field-effect transistor (FinFET) transistors, gate-all-around (GAA) transistors, nano-wire transistors, nano-sheet transistors, or a combination thereof. For the sake of providing an example, an exemplary GAA transistor is illustrated in FIG. 4. However, it should be understood that the application should not be limited to a particular type of device, except as specifically claimed.

Referring to FIG. 4, a perspective view of an exemplary GAA transistor 200 is illustrated. The GAA transistor 200 is formed over a substrate 202. The substrate 202 may contains a semiconductor material, such as bulk silicon (Si). In some embodiments, after the resultant GAA transistor 200 is formed, the substrate 202 may be removed by a suitable process (e.g., a chemical mechanical polishing (CMP) process) for forming back-side interconnection.

The GAA transistor 200 also includes one or more nanostructures 204 (dash lines) extending in the Y-direction and stacked vertically (or arranged) in the Z-direction. More specifically, the nanostructures 204 are spaced from each other in the Z-direction. In some embodiments, the nanostructures 204 may also be referred to as channels, channel layers, nanosheets, or nanowires.

The GAA transistor 200 further includes a gate structure 206 including a gate dielectric layer 208 and a gate electrode 210. The gate dielectric layer 208 wraps around the nanostructures 204 and the gate electrode 210 wraps around the gate dielectric layer 208 (not shown in FIG. 4, may refer to FIGS. 5B, 5C, and 5D). As shown in FIG. 4, gate spacers 212 are on sidewalls of the gate structure 206 and over the nanostructures 204 (not shown in FIG. 4, may refer to FIGS. 5C and 5D), in accordance with some embodiments. A gate top dielectric layer 214 is over the gate dielectric layer 208, the gate electrode 210, and the nanostructures 204. The gate top dielectric layer 214 is used for contact etch protection layer.

The GAA transistor 200 further includes source/drain features 216. As shown in FIG. 4, two source/drain features 216 are on opposite sides of the gate structure 206, in accordance with some embodiments. The nanostructures 204 (dash lines) extends in the Y-direction to connect one source/drain feature 216 to the other source/drain feature 216. The source/drain features 216 may also be referred to as source/drain, or source/drain regions. In some embodiments, source/drain feature(s) may refer to a source or a drain, individually or collectively dependent upon the context.

Isolation feature 218 is over the substrate 202 and under the gate dielectric layer 208, the gate electrode 210, and the gate spacers 212. The isolation feature 218 is used for isolating the GAA transistor 200 from other devices. In some embodiments, the isolation feature 218 may include different structures, such as shallow trench isolation (STI) structure, deep trench isolation (DTI) structure. Therefore, the isolation feature 218 is also referred as to as a STI feature or DTI feature.

FIG. 5A is a top view (or a layout) of an SRAM cell 100 that can be one embodiment of the SRAM cells implemented in the array, in accordance with some embodiments of the present disclosure. FIG. 5B is an X-Z cross-sectional view of the SRAM cell 100 along a line A-A′ in FIG. 5A, in accordance with some embodiments of the present disclosure. FIG. 5C is a Y-Z cross-sectional view of the SRAM cell 100 along a line B-B′ in FIG. 5A, in accordance with some embodiments of the present disclosure. FIG. 5D is a Y-Z cross-sectional view of the SRAM cell 100 along a line C-C′ in FIG. 5A, in accordance with some embodiments of the present disclosure.

As shown in FIG. 5A, the SRAM cell 100 has a cell boundary CB indicated by the dotted rectangular box and constructed by two cell long boundaries in the X-direction and two cell short boundaries in the Y-direction, in accordance with some embodiments. The SRAM cell 100 includes active areas, such as active areas 302-1 to 302-4, (may be collectively referred to as the active areas 302) that extend lengthwise in the Y-direction. Each of active areas 302 includes channel regions, source regions, and drain regions (where source regions and drain regions are collectively referred to as source/drain regions herein) of transistors. The SRAM cell 100 further includes gate structures, such as gate structures 304-1 to 304-4 (may be collectively referred to as the gate structures 304) that extend lengthwise in the X-direction perpendicular to the Y-direction. The gate structures 304-1 to 304-4 are disposed over the channel regions of the respective active areas 302-1 to 302-4 (i.e., (vertically stacked) nanostructures 310 and non-functional nanostructures 310′) and disposed between respective source/drain regions of the active areas 302-1 to 302-4 (i.e., source/drain features 312N and 312P). In some embodiments, the gate structures 304-1 to 304-4 wrap and/or surround suspended, vertically stacked nanostructures 310 in the channel regions of the active areas 302-1 to 302-4, respectively (as shown in FIGS. 5B, 5C, and 5D).

The gate structure 304-1 extends across the active area 302-1 in the top view and engages the active area 302-1 to form the pass-gate transistor PG-1; the gate structure 304-2 extends across the active areas 302-1 and 302-2 in the top view and engages the active area 302-1 and 302-2 to form the pull-down transistor PD-1 and the pull-up transistor PU-1 respectively; the gate structure 304-3 extends across the active areas 302-3 and 302-4 in the top view and engages the active area 302-3 and 302-4 to form the pull-up transistor PU-2 and the pull-down transistor PD-2 respectively; and the gate structure 304-4 extends across the active area 302-4 in the top view and engages the active area 302-4 to form the pass-gate transistor PG-2. Furthermore, the pull-down transistor PD-1 and the pull-up transistor PU-1 share the gate structure 304-2 to construct an inverter as the Inverter-1 discussed above, and the pull-down transistor PD-2 and the pull-up transistor PU-2 share the gate structure 304-3 to construct an inverter as the Inverter-2 discussed above. Therefore, the SRAM cell 100 includes the inverter having the pull-down transistor PD-1 and the pull-up transistor PU-1, and the inverter having the pull-down transistor PD-2 and the pull-up transistor PU-2. The gate structure 304-2 and the gate structure 304-3 are also referred to as common gates or shared gate structures.

Similar to the substrate 202 discussed above, referring to FIGS. 5B to 5D, the SRAM cell 100 includes a substrate 302, over which the various features are formed, such as the gate structures 304 above. The substrate 302 may contains a semiconductor material, such as bulk silicon (Si). In some other embodiments, the substrate 302 may include other semiconductors such as germanium (Ge), silicon germanium (SiGe), or a III-V semiconductor material. Example III-V semiconductor materials may include gallium arsenide (GaAs), indium phosphide (InP), gallium phosphide (GaP), gallium nitride (GaN), gallium arsenide phosphide (GaAsP), aluminum indium arsenide (AlInAs), aluminum gallium arsenide (AlGaAs), gallium indium phosphide (GaInP), and indium gallium arsenide (InGaAs). Alternatively, the substrate 302 may be a semiconductor-on-insulator substrate, such as a silicon-on-insulator (SOI) substrate, a silicon germanium-on-insulator (SGOI) substrate, or a germanium-on-insulator (GOI) substrate. Semiconductor-on-insulator substrates may be fabricated using separation by implantation of oxygen (SIMOX), wafer bonding, and/or other suitable methods.

In some embodiments, the n-type well NW and p-type wells PW are formed in or on the substrate 302, as shown in FIGS. 5B, 5C, and 5D. In the present embodiment, the p-type wells PW are p-type doped regions configured for n-type transistors (e.g., the pass-gate transistors PG-1 and PG-2 and the pull-down transistors PD-1 and PD-2), and the n-type well NW are n-type doped regions configured for p-type transistors (e.g., the pull-up transistors PU-1 and PU-2). The n-type well NW is doped with n-type dopants, such as phosphorus, arsenic, other n-type dopant, or a combination thereof. The p-type wells PW are doped with p-type dopants, such as boron, indium, other p-type dopant, or a combination thereof. In some implementations, the substrate 302 includes doped regions formed with a combination of p-type dopants and n-type dopants. The various n-type wells and/or p-type wells can be formed directly on and/or in the substrate 302, for example, providing a p-well structure, an n-well structure, a dual-well structure, a raised structure, or a combination thereof. An ion implantation process, a diffusion process, and/or other suitable doping process can be performed to form the various wells.

Similar to the isolation feature 218 discussed above, the SRAM cell 101A further includes an isolation feature (or isolation structure) 314. The isolation feature 314 may include silicon oxide, silicon nitride, silicon oxynitride, other suitable isolation material (for example, including silicon, oxygen, nitrogen, carbon, or other suitable isolation constituent), or a combination thereof. The isolation feature 314 may include different structures, such as shallow trench isolation (STI) structures, deep trench isolation (DTI) structures, and/or local oxidation of silicon (LOCOS) structures. In some embodiments, STI features include a multi-layer structure that fills the trenches, such as a silicon nitride comprising layer disposed over a thermal oxide comprising liner layer. In another example, STI features include a dielectric layer disposed over a doped liner layer (including, for example, boron silicate glass (BSG) or phosphosilicate glass (PSG)). In yet another example, STI features include a bulk dielectric layer disposed over a liner dielectric layer, where the bulk dielectric layer and the liner dielectric layer include materials depending on design requirements.

Each of the transistors in the SRAM cell 100 (e.g., the pass-gate transistors PG-1 and PG-2, the pull-down transistors PD-1 and PD-2, and the pull-up transistors PU-1 and PU-2) includes nanostructures 310 similar to the nanostructures 204 discussed above. As shown in FIGS. 5B, 5C, and 5D, the nanostructures 310 are suspended, in accordance with some embodiments. In some embodiments, three nanostructures 310 are vertically stacked (or vertically arranged) from each other in the Z-direction for one n-type transistor, such as the pass-gate transistors PG-1 and PG-2, and the pull-down transistors PD-1 and PD-2, as shown in FIGS. 5B and 5C. In some embodiments, two nanostructures 310 are vertically stacked (or vertically arranged) from each other in the Z-direction for one p-type transistor, such as the pull-up transistors PU-1 and PU-2, as shown in FIGS. 5B and 5D.

Furthermore, as shown in FIGS. 5B, 5C, and 5D, topmost surfaces of the nanostructures 310 of the pull-up transistors PU-1 and PU-2, the pass-gate transistors PG-1 and PG-2, and the pull-down transistors PD-1 and PD-2 are substantially level with each other, in accordance with some embodiments. In some embodiments, bottommost surfaces of the nanostructures 310 of the pull-up transistors PU-1 and PU-2 are higher than the bottommost surfaces of the nanostructures 310 of the pass-gate transistors PG-1 and PG-2 and the pull-down transistors PD-1 and PD-2, as shown in FIGS. 5B, 5C, and 5D. In other words, a distance from the topmost surface to the bottommost surface of the nanostructures 310 of the pull-up transistor PU-1 or the pull-up transistor PU-2 is less than a distance from the topmost surface to the bottommost surface of the nanostructures 310 of the pass-gate transistor PG-1, the pass-gate transistor PG-2, the pull-down transistor PD-1, or the pull-down transistor PD-2.

However, there may be another appropriate number of nanostructures in one transistor. For example, there may be from 2 to 10 nanostructures 310 in one transistor. The nanostructures 310 further extend lengthwise in the Y-direction (FIGS. 5A, 5C, and 5D) and widthwise in the X-direction (FIGS. 5A and 5B). In some embodiments, each of the nanostructures 310 has a thickness T in the Z-direction and in a range from about 3 nm to about 8 nm, as shown in FIG. 5B. As shown in FIG. 5B, in each of the transistors in the SRAM cell 100, two adjacent nanostructures 310 are spaced from each other in the Z-direction by a distance S in a range from about 6 nm to about 16 nm. In some embodiments, the nanostructures 310 vertically have a pitch P in the Z-direction and in a range from about 10 nm to about 24 nm.

The nanostructures 310 may include a semiconductor material, such as silicon, germanium, silicon carbide, silicon phosphide, gallium arsenide, gallium phosphide, indium phosphide, indium arsenide, and/or indium antimonide, silicon germanium (SiGe), SiPC, GaAsP, AlInAs, AlGaAs, GaInAs, GaInP, and/or GaInAsP. In some embodiments, the nanostructures 310 include silicon for n-type transistors. In other embodiments, the nanostructures 310 include silicon germanium for p-type transistors. In some embodiments, the nanostructures 310 are all made of silicon, and the type of the transistors depend on work function metal layer wrapping around the nanostructures 310. In some embodiments, the nanostructures 310 are epitaxially grown using a deposition technique such as epitaxial growth, vapor-phase epitaxy (VPE), molecular beam epitaxy (MBE), although other deposition processes, such as chemical vapor deposition (CVD), low pressure CVD (LPCVD), atomic layer deposition (ALD), ultrahigh vacuum CVD (UHVCVD), reduced pressure CVD (RPCVD), a combination thereof, or the like, may also be utilized.

As discussed above, each of the pass-gate transistors PG-1 and PG-2 and the pull-down transistors PD-1 and PD-2 has three nanostructures 310, and each of the pull-up transistors PU-1 and PU-2 has two nanostructures 310. Furthermore, in some embodiments, each of the pull-up transistors PU-1 and PU-2 includes a non-functional nanostructure 310′ under the nanostructures 310, as shown in FIGS. 5B and 5D. In some aspects, in each of the pull-up transistors PU-1 and PU-2, the non-functional nanostructure 310′ is between a bottommost surface of the nanostructures 310 and the substrate 302 in the Z-direction. The non-functional nanostructures 310′ are similar to the nanostructures 310, except that the non-functional nanostructures 310′ will not work or have no function in operation of the resultant SRAM cell 100. The non-functional nanostructures 310′ may be referred to as inactive channels, inactive channel layers, non-functional channels, non-functional channel layers, non-functional nanosheets, or non-functional nanowires. Relatively, the nanostructures 310 may be referred to as active channels, active channel layers, functional channels, functional channel layers, functional nanosheets, or functional nanowires.

Each of the gate structures 304-1 to 304-4 has a gate dielectric layer 306 and a gate electrode layer 308. The gate dielectric layers 306 wrap around each of the nanostructures 310 and the non-functional nanostructures 310′, and the gate electrodes layer 308 wrap around the gate dielectric layer 306. In some embodiments, the gate structures 304 each further includes an interfacial layer (such as having silicon dioxide, silicon oxynitride, or other suitable materials) between the gate dielectric layer 306 and the nanostructures 310. In some embodiments, the gate dielectric layers 306 have a thickness in a range from about 0.5 nm to about 3 nm. The gate dielectric layers 306 may include oxide with nitrogen doped dielectric material (initial layer) combined with metal content high-K dielectric material (K value (dielectric constant)>13). For example, gate dielectric layers 306 may include hafnium oxide (HfO₂), which has a dielectric constant in a range from about 18 to about 40. Alternatively, the gate dielectric layers 306 may include other high-K dielectrics, such as TiO₂, HfZrO, Ta₂O₃, HfSiO₄, ZrO₂, ZrSiO₂, LaO, AlO, ZrO, TiO, Ta₂O₅, Y₂O₃, SrTiO₃ (STO), BaTiO₃ (BTO), BaZrO, HfLaO, HfSiO, LaSiO, AlSiO, HfTaO, HfTiO, (Ba,Sr) TiO₃ (BST), Al₂O₃, Si₃N₄, oxynitrides (SiON), combinations thereof, or other suitable material. The gate dielectric layers 306 may be formed by chemical oxidation, thermal oxidation, ALD, CVD, and/or other suitable methods.

In some embodiments, the gate electrode layer 308 is formed to wrap around the gate dielectric layer 306 and the center portions of the nanostructures 310 and the non-functional nanostructures 310′, as shown in FIGS. 5C and 5D. In some embodiments, the gate electrode layer 308 may include an n-type work function metal layer for n-type transistor or a p-type work function metal layer for p-type transistor. In an embodiment the n-type work function metal layer is a material such as Ti, Al, Ag, Mn, Zr, TiAl, TiAlC, TaC, TaCN, TaSiN, TaAl, TaAlC, TiAlN, other suitable n-type work function materials, or combinations thereof. For example, the n-type work function metal layer may be deposited utilizing ALD, CVD, or the like. However, any suitable materials and processes may be utilized to form the n-type work function metal layer. In an embodiment, the p-type work function metal layer may be a material such as TiN, TaN, Ru, Mo, Al, WN, ZrSi₂, MoSi₂, TaSi₂, NiSi₂, WN, other metal oxides, metal nitrides, metal silicates, transition metal-oxides, transition metal-nitrides, transition metal-silicates, oxynitrides of metals, metal aluminates, zirconium silicate, zirconium aluminate, other suitable p-type work function materials, or combinations thereof. Additionally, the p-type work function metal layer may be deposited using a deposition process such as ALD, CVD, or the like, although any suitable deposition process may be used.

In some embodiments, the gate electrode layer 308 may include a single layer or alternatively a multi-layer structure. In some embodiments, the gate electrode layer 308 may further include a capping layer, a barrier layer, and a fill material (not shown). The capping layer may be formed adjacent to the gate dielectric layers 306 and may be formed from a metallic material such as TaN, Ti, TiAlN, TiAl, Pt, TaC, TaCN, TaSiN, Mn, Zr, TiN, Ru, Mo, WN, other metal oxides, metal nitrides, metal silicates, transition metal-oxides, transition metal-nitrides, transition metal-silicates, oxynitrides of metals, metal aluminates, zirconium silicate, zirconium aluminate, combinations of these, or the like. The metallic material may be deposited using a deposition process such as ALD, CVD, or the like, although any suitable deposition process may be used. The barrier layer may be formed adjacent the capping layer, and may be formed of a material different from the capping layer. For example, the barrier layer may be formed of a material such as one or more layers of a metallic material such as TiN, TaN, Ti, TiAlN, TiAl, Pt, TaC, TaCN, TaSiN, Mn, Zr, Ru, Mo, WN, other metal oxides, metal nitrides, metal silicates, transition metal-oxides, transition metal-nitrides, transition metal-silicates, oxynitrides of metals, metal aluminates, zirconium silicate, zirconium aluminate, combinations of these, or the like. The barrier layer may be deposited using a deposition process such as atomic layer deposition, chemical vapor deposition, or the like, although any suitable deposition process may be used.

The SRAM cell 100 further includes gate top dielectric layers 316 are over the gate dielectric layers 306, the gate electrodes 308, the nanostructures 310, and the non-functional nanostructures 310′. The gate top dielectric layers 316 are similar to the gate top dielectric layer 214 discussed above. The gate top dielectric layer 316 is used for contact etch protection layer.

In some embodiments, the gate top dielectric layer 316 has a thickness in a range from about 2 nm to about 60 nm. The material of gate top dielectric layer 316 is selected from a group consisting of oxide, SiOC, SiON, SiOCN, nitride base dielectric, metal oxide dielectric, Hf oxide (HfO₂), Ta oxide (Ta₂O₅), Ti oxide (TiO₂), Zr oxide (ZrO₂), Al oxide (Al₂O₃), Y oxide (Y₂O₃), combinations thereof, or other suitable material.

As shown in FIG. 5B, gate end dielectrics 318 are at ends of the gate structures 304, in accordance with some embodiments. The gate end dielectrics 318 are used for separating the gate structures 304 aligned in the X-direction. For example, the gate end dielectrics 318 separate the gate structures 304-1 and 304-3, as shown in FIG. 5B. The material of the gate end dielectrics 318 is selected from a group consisting of Si₃N₄, nitride-base dielectric, carbon-base dielectric, high K material (K>=9), or a combination thereof.

In some embodiments, the SRAM cell 100 further includes gate spacers 320 are on sidewalls of the gate structures 304 and over the nanostructures 310 and the non-functional nanostructures 310′, as shown in FIGS. 5C and 5D. More specifically, the gate spacers 320 are over the nanostructures 310 and the non-functional nanostructures 310′ and on top sidewalls of the gate structures 304, and thus are also referred to as gate top spacers or top spacers. The gate spacers 320 may include multiple dielectric materials and be selected from a group consisting of silicon nitride (Si₃N₄), silicon oxide (SiO₂), silicon carbide (SiC), silicon oxycarbide (SiOC), silicon oxynitride (SiON), silicon oxycarbon nitride (SiOCN), carbon doped oxide, nitrogen doped oxide, porous oxide, air gap, or a combination thereof. In some embodiments, the gate spacers 320 may include a single layer or a multi-layer structure.

As shown in FIGS. 5C and 5D, the SRAM cell 100 further includes inner spacers 322 on the sidewalls of the gate structures 304 and below the topmost nanostructures 310, in accordance with some embodiments. Furthermore, the inner spacers 322 are laterally between the source/drain features 312N (or 312P) and the gate structures 304. The inner spacers 322 are also vertically between adjacent nanostructures 310, vertically between one nanostructure 310 and one non-functional nanostructure 310′, vertically between one nanostructure 310 and the substrate 302, or vertically between one non-functional nanostructure 310′ and the substrate 302. The inner spacers 322 may include a dielectric material having higher K value (dielectric constant) than the gate spacers 320 and be selected from a group consisting of silicon nitride (Si₃N₄), silicon oxide (SiO₂), silicon carbide (SiC), silicon oxycarbide (SiOC), silicon oxynitride (SiON), silicon oxycarbon nitride (SiOCN), air gap, or a combination thereof. In some embodiments, the inner spacers 322 may include a dielectric material having lower K value (dielectric constant) than the gate spacers 320. In some embodiments, the gate spacers 320 have a thickness in the Y-direction and in a range from about 3 nm to about 15 nm. In some embodiments, the inner spacers 322 have a thickness in the Y-direction and in a range from about 3 nm to about 12 nm. In some embodiments, the thickness of the gate spacers 320 in the Y-direction and the thickness of the inner spacers 322 in the Y-direction are the same. In other embodiments, the thickness of the gate spacers 320 in the Y-direction is less than the thickness of the inner spacers 322 in the Y-direction due to the gate spacers 320 being trimmed in sequent processes for forming source/drain contacts.

Referring to FIGS. 5C and 5D, each of the transistors in the SRAM cell 100 (e.g., the pass-gate transistors PG-1 and PG-2, the pull-down transistors PD-1 and PD-2, and the pull-up transistors PU-1 and PU-2) further include isolation layers 311 over the substrate 302. More specifically, the isolation layers 311 are vertically sandwiched between the source/drain features 312N/312P and the substrate 302. Furthermore, in some embodiments, the isolation layers 311 are on opposite sides of the gate structures 304 in the Y-direction, as shown in FIGS. 5C and 5D. As shown in FIG. 5D, the isolation layers 311 in the pull-up transistors PU-1 and PU-2 are in contact with and on opposite sides of the non-functional nanostructures 310′ in the Y-direction, in accordance with some embodiments. In other words, the non-functional nanostructures 310′ are between the isolation layers 311 in the Y-direction. As such, the non-functional nanostructures 310′ is turned off, blocked, and disabled by the isolation layers 311. Therefore, as discussed above, the non-functional nanostructures 310′ will not work or have no function in operation of the resultant SRAM cell 100.

As shown in FIG. 5D, top surfaces of the isolation layers 311 of the pull-up transistors PU-1 and PU-2 are higher than top surfaces of the non-functional nanostructures 310′, in accordance with some embodiments. Furthermore, bottom surfaces of the isolation layers 311 are lower than bottom surfaces of the non-functional nanostructures 310′, bottommost surfaces of the gate structures 304, and topmost surfaces of the substrate 302. As shown in FIGS. 5C and 5D, the isolation layers 311 extend into the substrate 302 by about 2 nm to about 20 nm, in accordance with some embodiments. In other words, a distance D1 between the topmost surfaces of the substrate 302 and the bottom surfaces of the isolation layers 311 is in a range from about 2 nm to about 20 nm.

In some embodiments, a thickness of the isolation layers 311 of the pull-up transistor PU-1 and PU-2 is greater than a thickness of the isolation layers 311 of the pass-gate transistors PG-1 and PG-2 and the pull-down transistors PD-1 and PD-2. In some embodiments, the thickness of the isolation layers 311 of the pull-up transistor PU-1 and PU-2 is in a range from about 10 nm to about 50 nm. In some embodiments, the thickness of the isolation layers 311 of the pass-gate transistors PG-1 and PG-2 and the pull-down transistors PD-1 and PD-2 is in a range from about 5 nm to about 25 nm. The difference in thickness between the isolation layers 311 of the pull-up transistors PU-1 and PU-2 and the isolation layers 311 of the pass-gate transistors PG-1 and PG-2 and the pull-down transistors PD-1 and PD-2 is in a range from about 5 nm to about 35 nm.

In some embodiments, the isolation layers 311 may include a single dielectric layer or alternatively a multiple dielectric layers. The isolation layers 311 may include dielectric materials and be selected from a group consisting of silicon nitride (Si₃N₄), silicon oxide (SiO₂), silicon carbide (SiC), silicon oxycarbide (SiOC), silicon oxynitride (SiON), silicon oxycarbon nitride (SiOCN), carbon doped oxide, nitrogen doped oxide, porous oxide, air gap, or a combination thereof.

Referring to FIGS. 5C and 5D, each of the transistors in the SRAM cell 100 (e.g., the pass-gate transistors PG-1 and PG-2, the pull-down transistors PD-1 and PD-2, and the pull-up transistors PU-1 and PU-2) further includes source/drain features 312N or source/drain features 312P over the isolation layers 311 and in the source/drain regions of the active areas 302. More specifically, the source/drain features 312N are disposed over the isolation layers 311 and on opposite sides of the respective gate structure 304 and nanostructures 310, and connected by the nanostructures 310 to form n-type transistor (e.g., the pass-gate transistors PG-1 and PG-2, the pull-down transistors PD-1 and PD-2). Similarly, the source/drain features 312P are disposed over the isolation layers 311 and on opposite sides of the respective gate structure 304 and nanostructures 310, and connected by the nanostructures 310 to form p-type transistor (e.g., the pull-up transistors PU-1 and PU-2).

In some embodiments, bottom surfaces of the source/drain features 312N and 312P are in contact with the top surfaces of the isolation layers 311, as shown in FIGS. 5C and 5D. Furthermore, as shown in FIGS. 5C and 5D, the source/drain features 312N and 312P are separated from the substrate 302 by the isolation layers 311 in the Z-direction, in accordance with some embodiments. Top surfaces of the source/drain features 312N and 312P are substantially level with topmost surfaces of the nanostructures 310. In some embodiments, the bottom surfaces of the source/drain features 312N of the pass-gate transistors PG-1 and PG-2 and the pull-down transistors PD-1 and PD-2 are lower than the bottom surfaces of the source/drain features 312P of the pull-up transistors PU-1 and the PU-2. As such, a thickness of the source/drain features 312N is greater than a thickness of the source/drain features 312P. As shown in FIG. 5D, the bottom surfaces of the source/drain features 312P of the pull-up transistors PU-1 and PU-2 are higher than top surfaces of the non-functional nanostructures 310′, in accordance with some embodiments. Furthermore, in some embodiments, the bottom surfaces of the source/drain features 312N and 312P are higher than the bottommost surfaces of the gate structures 304, and the topmost surfaces of the substrate 302.

The source/drain features 312N and 312P may be formed by using epitaxial growth. In some embodiments, the source/drain features 312N may include epitaxially-grown material selected from a group consisting of SiP, SiC, SiPC, SiAs, Si, or a combination thereof. In some embodiments, the epitaxially-grown material of the source/drain features 312N may be doped with phosphorus (or arsenic, or both) having a doping concentration in a range from about 2×10₁₉/cm³ to 3×10²¹/cm³. In some embodiments, the source/drain features 312P may include epitaxially-grown material selected from a group consisting of boron-doped SiGe, boron-doped SiGeC, boron-doped Ge, boron-doped Si, boron and carbon doped SiGe, or a combination thereof. In some embodiments, the epitaxially-grown material of the source/drain features 312P may be doped with boron having a doping concentration in a range from about 1×10¹⁹/cm³ to 6×10²⁰/cm³.

For maximum density to be achieved in SRAM chip, the SRAM cells must be laid out in as small a size as possible. To have small cell size, it should be layout to the limitations of both process margin and devices dimension. However, SRAM cell write capability is strongly correlated to ratio of on-current of the pass-gate transistors to on-current of the pull-up transistors (Ion-PG/Ion-PU). The on-current of the pass-gate transistors should be greater than the on-current of the pull-up transistors. To maintain a proper ratio that may require larger width for pass-gate transistors and therefore impact the SRAM cell size.

As shown in FIGS. 5C and 5D, each of the pass-gate transistors PG-1 and PG-2 and the pull-down transistors PD-1 and PD-2 has three nanostructures 310 connected to the source/drain features 312N, and each of the pull-up transistors PU-1 and PU-2 has two nanostructures 310 connected to the source/drain features 312P, as discussed above. In other words, a number of the nanostructures 310 of the pull-up transistor PU-1 or the pull-up transistor PU-2 is less than a number of the nanostructures 310 of the pass-gate transistor PG-1, the pass-gate transistor PG-2, the pull-down transistor PD-1, or the pull-down transistor PD-2. This means that the on-current of the pass-gate transistors PG-1 and PG-2 and the pull-down transistors PD-1 and PD-2 are higher than the on-current of the pull-up transistors PU-1 and PU-2. Therefore, the ratio of on-current of the pass-gate transistors to on-current of the pull-up transistors (Ion-PG/Ion-PU) is maintained by reducing the number of the functional nanostructures 310 of the pull-up transistors PU-1 and PU-2 without the need to reduce the SRAM cell size and thereby impact the process margin. Furthermore, the isolation layers 311 prevent the leakage current of the resultant transistors of the SRAM cell from one source/drain feature 312N/312P to another source/drain feature 312N/312P through the substrate 302, thereby improving the performance of the SRAM cell.

As shown in FIGS. 5C and 5D, the SRAM cell 100 further includes silicide features 324 over the source/drain features 312N and 312P. The silicide features 324 may include titanium silicide (TiSi), nickel silicide (NiSi), tungsten silicide (WSi), nickel-platinum silicide (NiPtSi), nickel-platinum-germanium silicide (NiPtGeSi), nickel-germanium silicide (NiGeSi), ytterbium silicide (YbSi), platinum silicide (PtSi), iridium silicide (IrSi), erbium silicide (ErSi), cobalt silicide (CoSi), or other suitable compounds.

Referring to FIGS. 5A, 5C, and 5D, the SRAM cell 100 further includes source/drain contacts 330 (including source/drain contacts 330-1 to 330-8). As shown in FIG. 5A, the source/drain contacts 330 extend lengthwise in the X-direction. In some embodiments, the source/drain contacts 330 are self-aligned source/drain contacts. This means that the source/drain contacts 330 are formed by using the gate spacers 320 as mask. Therefore, the source/drain contacts 330 are in direct contact with the gate spacers 320, as shown in FIGS. 5C and 5D. In some embodiments, the gate spacers 320 are trimmed due to the gate spacers 320 serving as the mask for forming the source/drain contacts 330. Therefore, the thickness of the gate spacers 320 in the Y-direction is less than the thickness of the inner spacers 322 in the Y-direction, as discussed above. As shown in FIGS. 5C and 5D, top surfaces of the source/drain contacts 330 are substantially level with top surfaces of the gate top dielectric layers 316, in accordance with some embodiments.

In other embodiments, the source/drain contacts 330 are non-self-aligned source/drain contacts. In these cases, the top surfaces of the source/drain contacts 330 are higher than the top surfaces of the gate top dielectric layers 316 by at least 10 nm. Furthermore, in some embodiments, the top surfaces of the source/drain contacts 330 are substantially level with top surfaces of the gate structures 304.

Furthermore, each of the source/drain contacts 330 is over and electrically connected to the respective source/drain features 312N/312P. Specifically, as shown in FIG. 5A, the source/drain contact 330-1 is over and electrically connected to the source/drain feature 312N of the pass-gate transistor PG-1; the source/drain contact 330-2 is over and electrically connected to the source/drain feature 312P of the pull-up transistor PU-2; the source/drain contact 330-3 is over and electrically connected to the source/drain feature 312N of the pull-down transistor PD-2; the source/drain contact 330-4 is over and electrically connected to the source/drain feature 312N of (or shared by) the pass-gate transistor PG-1 and pull-down transistor PD-1 (also referred to as common source/drain or common drain) and the source/drain feature 312P of the pull-up transistor PU-1; the source/drain contact 330-5 is over and electrically connected to the source/drain feature 312N of (or shared by) the pass-gate transistor PG-2 and pull-down transistor PD-2 (also referred to as common source/drain or common drain) and the source/drain feature 312P of the pull-up transistor PU-2; the source/drain contact 330-6 is over and electrically connected to the source/drain feature 312N of the pull-down transistor PD-1; the source/drain contact 330-7 is over and electrically connected to the source/drain feature 312P of the pull-up transistor PU-1; and the source/drain contact 330-8 is over and electrically connected to the source/drain feature 312N of the pass-gate transistor PG-2.

The SRAM cell 100 further includes butted contacts 332-1 and 332-2. As shown in FIGS. 5A and 5D, the butted contact 332-1 is over the source/drain contact 330-4 and the gate structure 304-3, and the butted contact 332-2 is over the source/drain contact 330-5 and the gate structure 304-2. In some embodiments, the butted contact 332-1 electrically connects the source/drain contact 330-4 to the gate structure 304-3 and the butted contact 332-2 electrically connects the source/drain contact 330-5 to the gate structure 304-2. The butted contacts 332-1 and the source/drain contact 330-4 may correspond to the storage node SN shown in FIG. 2 and the butted contacts 332-2 and the source/drain contact 330-5 may correspond to the storage node SNB shown in FIG. 2. The source/drain contacts 330 and butted contacts 332-1 and 332-2 may each include a conductive material such as Al, Cu, W, Co, Ti, Ta, Ru, Rh, Ir, Pt, TiN, TiAl, TiAlN, TaN, TaC, combinations of these, or the like, although any suitable material may be deposited using a deposition process such as sputtering, CVD, electroplating, electroless plating, or the like. In some embodiments, the source/drain contacts 330 and butted contacts 332-1 and 332-2 may each include single conductive material layer or multiple conductive layers.

The SRAM cell 100 further includes a (front-side) interconnection structure 402 including vias 404 (including vias 404-1 to 404-6), metal conductors 406 (including metal conductors 406-1 to 406-7), vias 408 (including vias 408-1 to 408-4), metal conductors 410 (including metal conductors 410-1 and 410-3), vias 412 (including vias 412-1 to 412-2), metal conductors 414 (including metal conductors 414-1 and 414-2), gate vias 416 (including gate vias 416-1 and 416-2), and an inter-layer dielectric (ILD) layer 418, which are over (or at the front-side of) the transistors in the SRAM cell 100 (e.g., the pass-gate transistors PG-1 and PG-2, the pull-down transistors PD-1 and PD-2, and the pull-up transistors PU-1 and PU-2).

The metal conductors 406 are in a metal layer ML1 in the ILD layer 418 and extend lengthwise in the Y-direction. The metal conductors 406 are in a (front-side) metal layer ML2 in the ILD layer 418 and extend lengthwise in the X-direction. The metal conductors 410 are in a (front-side) metal layer ML3 in the ILD layer 418 and extend lengthwise in the Y-direction. The metal layer ML1 is over the SRAM cell 100, and the metal layer ML2 is over the metal layer ML1, and the metal layer ML3 is over the metal layer ML2, and thus the metal conductors 406 are over the transistors of the SRAM cell 100, the metal conductors 410 are over the metal conductors 406, and the metal conductors 414 are over the metal conductors 410.

Each of the vias 404 in the ILD layer 418 are vertically between and electrically connected to the respective source/drain contact 330 and the respective metal conductor 406. Each of the gate vias 416 in the ILD layer 418 are vertically between and electrically connected to the respective gate structure 304 and the respective metal conductor 406. Each of the vias 408 in the ILD layer 418 are vertically between and electrically connected to the respective metal conductor 406 and the respective metal conductor 410. Each of the vias 412 in the ILD layer 418 are vertically between and electrically connected to the respective metal conductor 410 and the respective metal conductor 414. In some embodiments, the vias 404, the vias 408, vias 412, and the gate vias 416 may have circular shape in the top view. In other embodiments, the vias 404, the vias 408, and the vias 412 may have a rectangular shape in the top view.

As shown in FIG. 5A, in the top view, the vias 404, 408, 412, and the gate vias 416 overlap the cell boundary CB, in accordance with some embodiments. In some embodiments, the vias 408-2 and 408-3 are directly over and overlap the vias 404-4 and 404-3; and the vias 412-1 and 412-2 are directly over and overlap the vias 408-2 and 408-3, as shown in FIG. 5A. Furthermore, in the top view, the metal conductors 406-1, 406-2, 406-6, 406-7, 410-1, 410-3, 414-1, and 417-2 lengthwise overlap the cell boundary CB.

In some embodiments, the metal conductor 410-2 serves as the word-line that is electrically connected to the gate structures 304 (more specifically, the gate electrodes 308) of the pass-gate transistors PG-1 and PG-2 in the SRAM cell 100. As shown in FIGS. 5A to 5D, in the SRAM cell 100, the metal conductor 410-2 is over the pass-gate transistor PG-1 and PG-2. The metal conductor 410-2 is electrically connected to the gate structure 304-1 of the pass-gate transistor PG-1 through the via 408-1, the metal conductor 406-1, and the gate via 416-1, and is electrically connected to the gate structure 304-4 of the pass-gate transistor PG-2 through the via 408-4, the metal conductor 406-7, and the gate via 416-2. In some embodiments, the metal conductor 410-2 may be referred to as (front-side) word-line conductor. In some embodiments, the metal conductors 406-1 and 406-7 may be referred to as word-line landing pads.

In some embodiments, the metal conductors 414-1 and 414-2 serve as the VSS lines that are electrically coupled to a voltage node or voltage source (not shown) (e.g., the voltage node (or voltage source) VSS) and electrically connected to the source/drain features 312N of the pull-down transistors PD-1 and PD-2 in the SRAM cell 100. As shown in FIGS. 5A to 5D, in the SRAM cell 100, the metal conductor 414-1 and 414-2 are respectively over the pull-down transistors PD-1 and PD-2. The metal conductor 414-1 is electrically connected to the source/drain features 312N of the pull-down transistor PD-1 through the via 412-1, the metal conductors 410-3, the via 408-2, the metal conductors 406-2, the via 404-4, and the source/drain contact 330-6; and the metal conductor 414-2 is electrically connected to the source/drain features 312N of the pull-down transistor PD-2 through the via 412-2, the metal conductors 410-1, the via 408-3, the metal conductors 406-6, the via 404-3, and the source/drain contact 330-3. In some embodiments, the metal conductors 414-1 and 414-2 may be referred to as (front-side) VSS conductors or (front-side) VSS lines.

In some embodiments, the metal conductor 406-4 serves as the VDD line that is electrically coupled to a voltage node or voltage source (not shown) (e.g., the voltage node (or voltage source) VDD) and electrically connected to the source/drain features 312P of the pull-up transistors PU-1 and PU-2 in the SRAM cell 100. As shown in FIGS. 5A to 5D, in the SRAM cell 100, the metal conductor 406-4 is over the pull-up transistors PU-1 and PU-2. The metal conductor 406-4 is electrically connected to the source/drain features 312P of the pull-up transistor PU-1 through the via 404-5 and the source/drain contact 330-7, and is electrically connected to the source/drain features 312P of the pull-up transistor PU-2 through the via 404-2 and the source/drain contact 330-2. In some embodiments, the metal conductor 406-4 may be referred to as the (front-side) VDD conductors or the (front-side) VDD lines.

In some embodiments, the metal conductors 406-3 and 406-5 respectively serve as the bit-line and the bit-line-bar that are electrically connected to the source/drain features 312N of the pass-gate transistors PG-1 and PG-2 in the SRAM cell 100. As shown in FIGS. 5A to 5D, in the SRAM cell 100, the metal conductor 406-3 and 406-5 are respectively over the pass-gate transistor PG-1 and PG-2. The metal conductor 406-3 is electrically connected to the source/drain feature 412N of the pass-gate transistor PG-1 through the via 604-1 and the source/drain contact 432-1, and the metal conductor 406-5 is electrically connected to the source/drain feature 412N of the pass-gate transistor PG-2 through the via 604-4 and the source/drain contact 432-4. In some embodiments, the metal conductors 406-3 and 406-5 may be respectively referred to as (front-side) bit-line conductor and (front-side) bit-line-bar conductor.

The ILD layer 418 may include one or more dielectric layers including dielectric materials, such as tetraethylorthosilicate (TEOS) oxide, un-doped silicate glass, or doped silicon oxide such as borophosphosilicate glass (BPSG), fluoride-doped silica glass (FSG), phosphosilicate glass (PSG), boron doped silicon glass (BSG), a low-k dielectric material, other suitable dielectric material, or a combination thereof.

The materials of the vias 404, the metal conductors 406, the vias 408, the metal conductors 410, vias 412, metal conductors 414, the gate vias 416 are selected from a group consisting of titanium (Ti), titanium nitride (TiN), tantalum (Ta), tantalum nitride (TaN), titanium aluminum nitride (TiAlN), tungsten nitride (WN), tungsten (W), cobalt (Co), molybdenum (Mo), ruthenium (Ru), platinum (Pt), aluminum (Al), copper (Cu), other conductive materials, or a combination thereof.

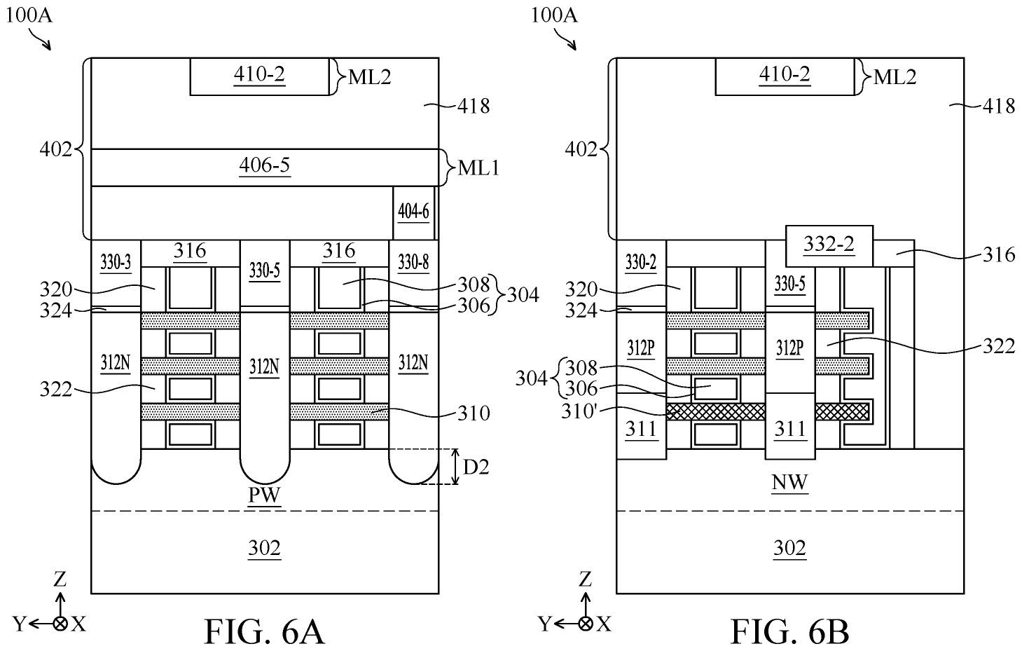

FIGS. 6A and 6B are Y-Z cross-sectional views of an alternative SRAM cell (e.g., an SRAM cell 100A) along the lines B-B′ and C-C′ in FIG. 5A, respectively, in accordance with some alternative embodiments of the present disclosure. The SRAM cell 100A is similar to the SRAM cell 100 discussed above, except that the isolation layers 311 in the pass-gate transistors PG-1 and PG-2 and the pull-down transistors PD-1 and PD-2 are omitted. As shown in FIG. 6A, the source/drain features 312N of the pass-gate transistors PG-1 and PG-2 and the pull-down transistors PD-1 and PD-2 extend into the substrate 302, in accordance with some embodiments. Therefore, the source/drain features 312N of the pass-gate transistors PG-1 and PG-2 and the pull-down transistors PD-1 and PD-2 are in contact with the substrate 302, and the source/drain features 312P of the pull-up transistors PU-1 and PU-2 are separated from the substrate 302 by the isolation layers 311. In some embodiments, the source/drain features 312N each has a convex bottom surfaces, as shown in FIG. 6A. Furthermore, the bottom surfaces of the source/drain features 312N are lower than the topmost surfaces of the substrate 302 and the bottommost surfaces of the gate structures 304. In some embodiments, a distance D2 between the topmost surfaces of the substrate 302 and the bottom surfaces of the source/drain features 312N is in a range from about 5 nm to about 50 nm.

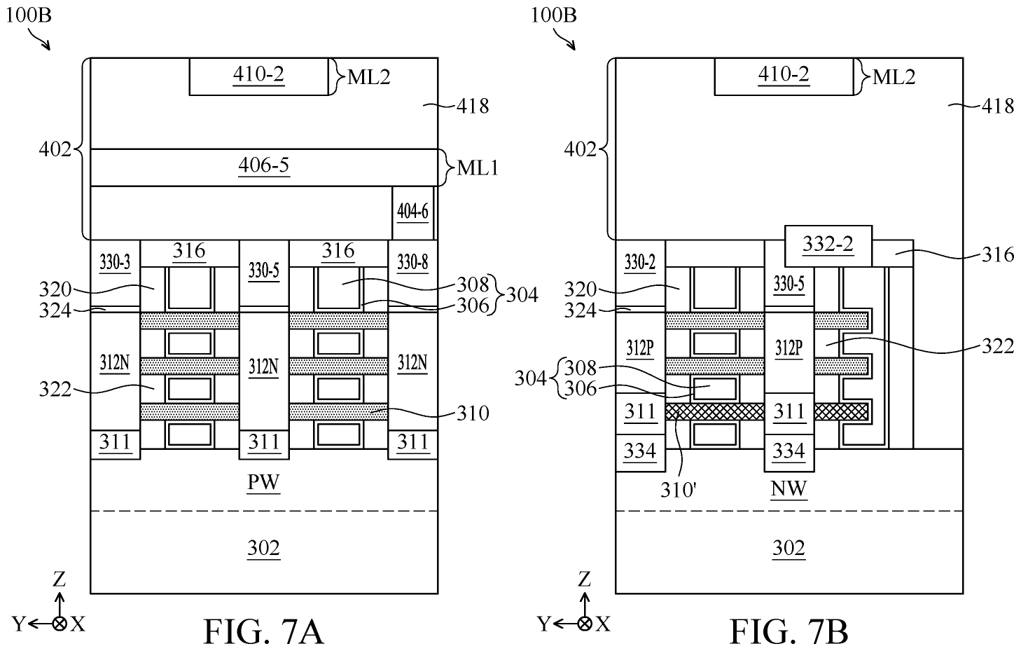

FIGS. 7A and 7B are Y-Z cross-sectional views of an alternative SRAM cell (e.g., an SRAM cell 100B) along the lines B-B′ and C-C′ in FIG. 5A, respectively, in accordance with some alternative embodiments of the present disclosure. The SRAM cell 100B is similar to the SRAM cell 100 discussed above, except that each of the pull-up transistors PU-1 and PU-2 further includes epitaxial layers 334 over the substrate 302 in the Z-direction. More specifically, as shown in FIG. 7B, the epitaxial layers 334 are vertically sandwiched between the isolation layers 311 of the pull-up transistors PU-1 and PU-2 and the substrate 302. Therefore, in some aspects, the isolation layers 311 of the pull-up transistors PU-1 and PU-2 are separated from the substrate 302 by the epitaxial layers 334. In some embodiments, the epitaxial layers 334 include silicon. As such, the epitaxial layers 334 may be referred to as silicon layers or epitaxy silicon layers.

In the present embodiments, a thickness of the isolation layers 311 of the pull-up transistors PU-1 and PU-2 is equal to a thickness of the isolation layers 311 of the pass-gate transistors PG-1 and PG-2 and the pull-down transistors PD-1 and PD-2. In some embodiments, the thickness of the isolation layers 311 of the pull-up transistors PU-1 and PU-2, the pass-gate transistors PG-1 and PG-2, and the pull-down transistors PD-1 and PD-2 is in a range from about 5 nm to about 25 nm.

Furthermore, in some embodiments, top surfaces of the epitaxial layers 334 are lower than the bottommost surfaces of the nanostructures 310 of the pull-up transistors PU-1 and PU-2, and higher than the topmost surfaces of the substrate 302 and the bottommost surfaces of the gate structures 304, as shown in FIG. 7B. In other words, the bottom surfaces of the isolation layers 311 of the pull-up transistors PU-1 and PU-2 are higher than the topmost surfaces of the substrate 302 and the bottommost surfaces of the gate structures 304. The top surfaces of the epitaxial layers 334 are higher than the topmost surfaces of the substrate 302 by a range from about 2 nm to about 20 nm. In some aspects, the isolation layers 311 of the pull-up transistors PU-1 and PU-2 are higher than the topmost surfaces of the substrate 302 by a range from about 2 nm to about 20 nm.

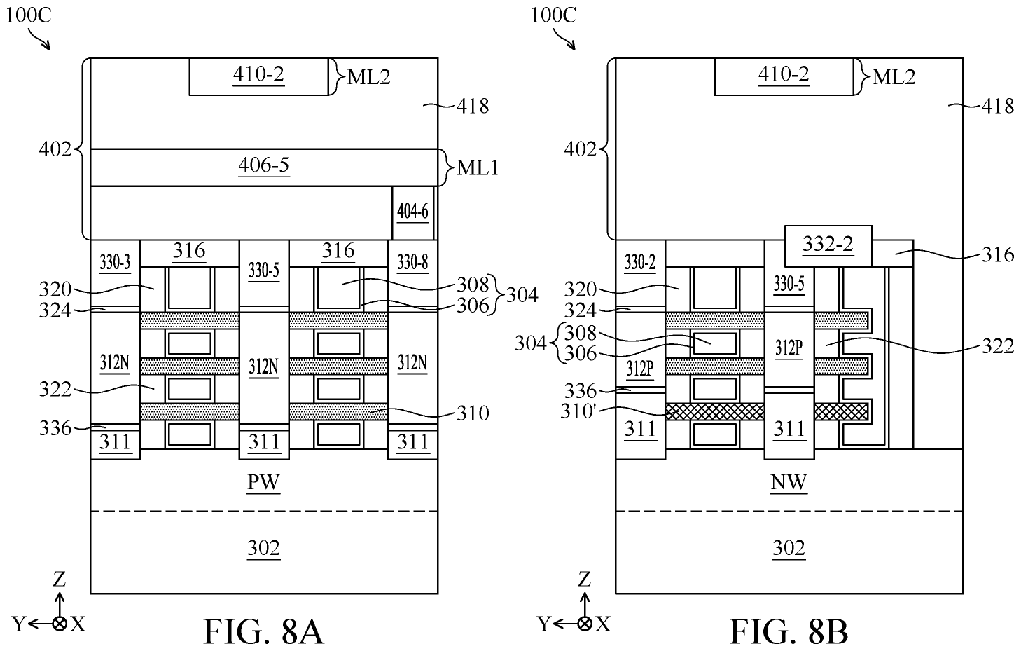

FIGS. 8A and 8B are Y-Z cross-sectional views of an alternative SRAM cell (e.g., an SRAM cell 100C) along the lines B-B′ and C-C′ in FIG. 5A, respectively, in accordance with some alternative embodiments of the present disclosure. The SRAM cell 100C is similar to the SRAM cell 100 discussed above, except that each of the pull-up transistors PU-1 and PU-2, the pass-gate transistors PG-1 and PG-2, and the pull-down transistors PD-1 and PD-2 further includes air gaps 336 over the isolation layers 311. More specifically, as shown in FIGS. 8A and 8B, the air gaps 336 are between the source/drain features 312N/312P and the isolation layers 311 in the Z-direction, in accordance with some embodiments. In other words, the air gaps 336 separate the source/drain features 312N/312P from the isolation layers 311. The air gaps 336 have air with lower K value (dielectric constant) of about 1. Therefore, the parasitic capacitance of the SRAM cell 100C is reduced, thereby improving the performance of the SRAM cell 100C.

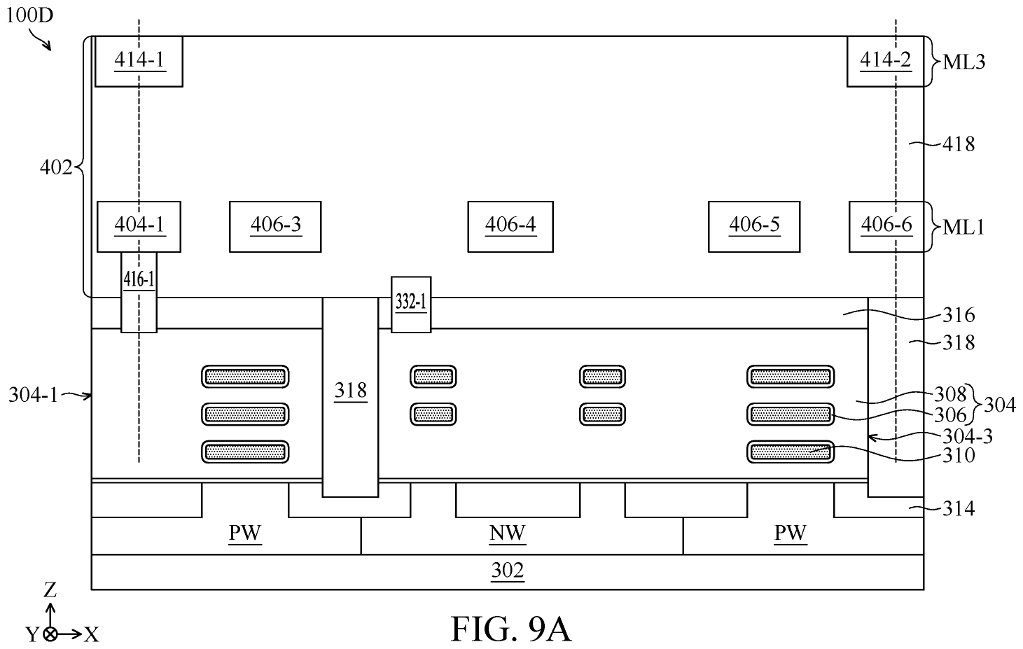

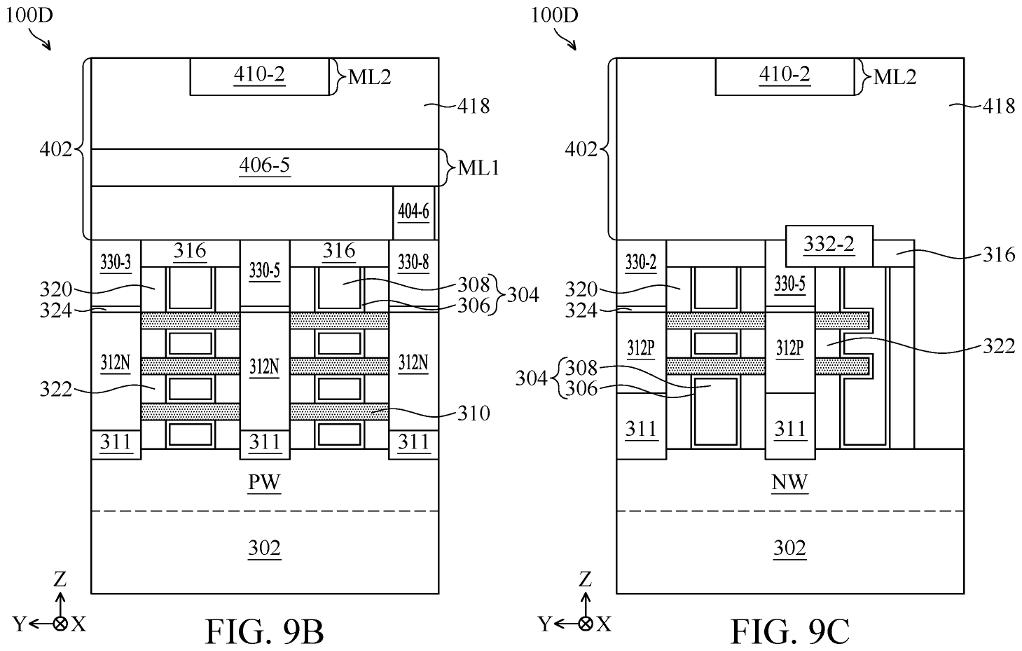

FIG. 9A is an X-Z cross-sectional views of an alternative SRAM cell (e.g., an SRAM cell 100D) along the line A-A′ in FIG. 5A, in accordance with some alternative embodiments of the present disclosure. FIGS. 9B and 9C are Y-Z cross-sectional views of the alternative SRAM cell (e.g., the SRAM cell 100D) along the lines B-B′ and C-C′ in FIG. 5A, respectively, in accordance with some alternative embodiments of the present disclosure.

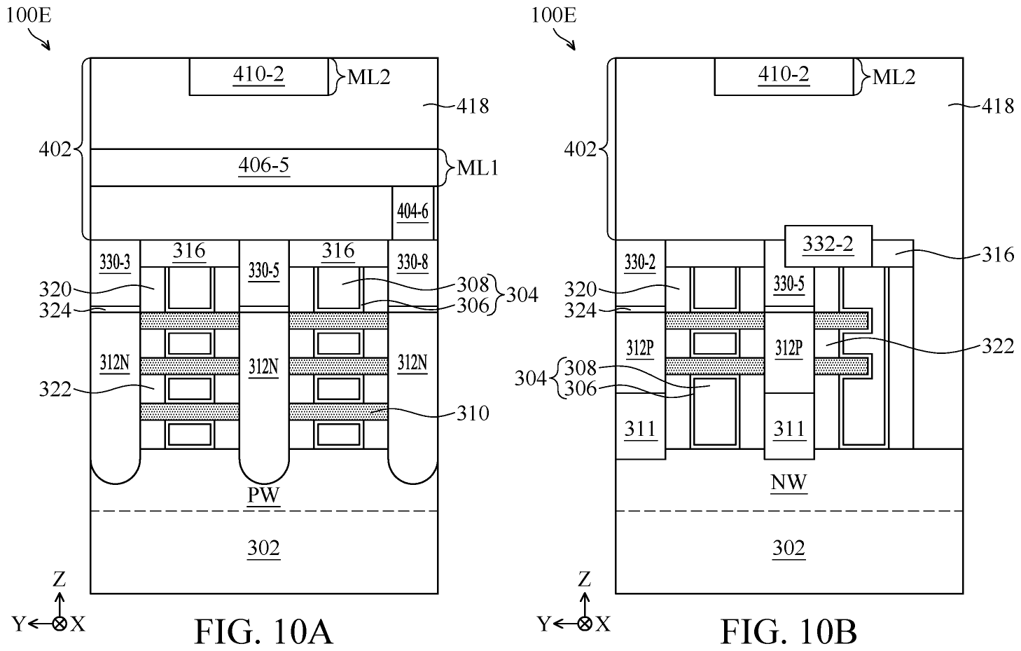

FIGS. 10A and 10B are Y-Z cross-sectional views of an alternative SRAM cell (e.g., an SRAM cell 100E) along the lines B-B′ and C-C′ in FIG. 5A, respectively, in accordance with some alternative embodiments of the present disclosure. The SRAM cell 100E is similar to the SRAM cell 100A discussed above, except that the non-functional nanostructures 310′ of the pull-up transistors PU-1 and PU-2 are omitted.

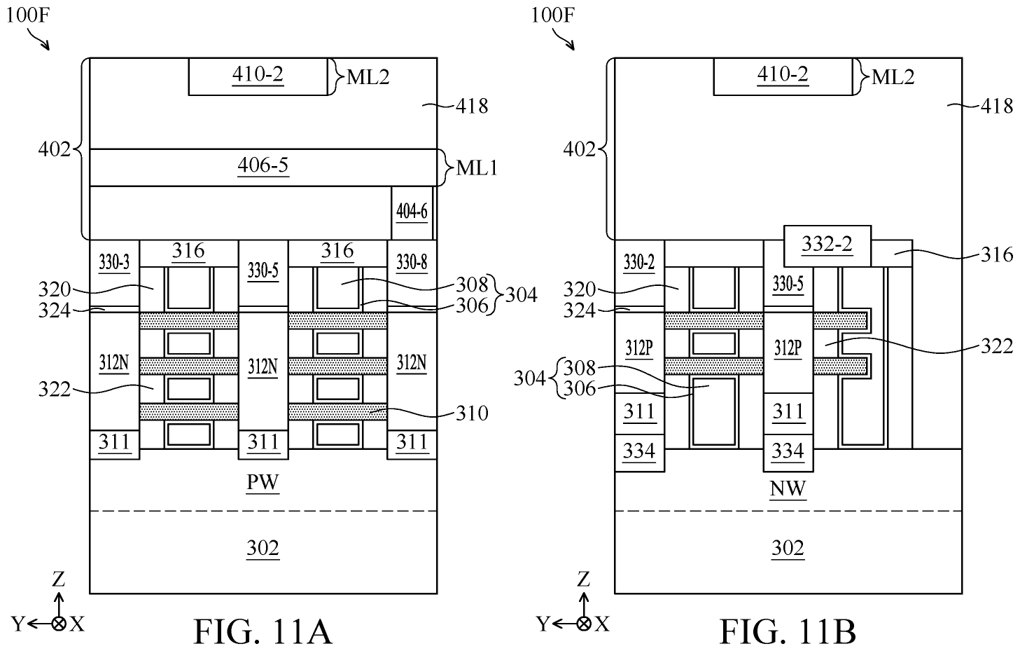

FIGS. 11A and 11B are Y-Z cross-sectional views of an alternative SRAM cell (e.g., an SRAM cell 100F) along the lines B-B′ and C-C′ in FIG. 5A, respectively, in accordance with some alternative embodiments of the present disclosure. The SRAM cell 100F is similar to the SRAM cell 100B discussed above, except that the non-functional nanostructures 310′ of the pull-up transistors PU-1 and PU-2 are omitted.

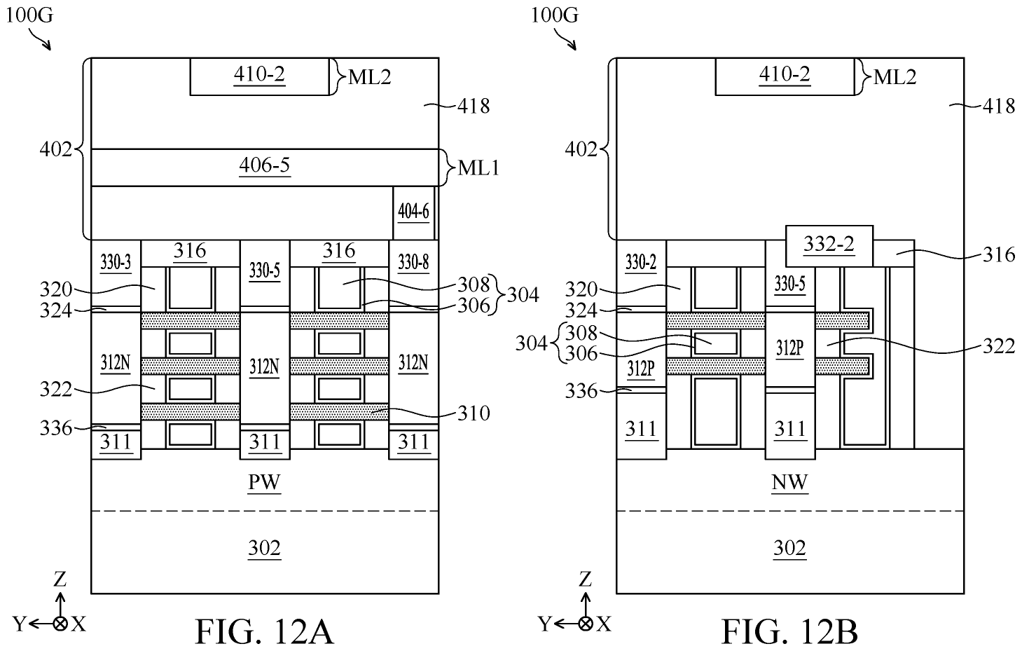

FIGS. 12A and 12B are Y-Z cross-sectional views of an alternative SRAM cell (e.g., an SRAM cell 100G) along the lines B-B′ and C-C′ in FIG. 5A, respectively, in accordance with some alternative embodiments of the present disclosure. The SRAM cell 100G is similar to the SRAM cell 100C discussed above, except that the non-functional nanostructures 310′ of the pull-up transistors PU-1 and PU-2 are omitted.

The SRAM cells 100D, 100E, 100F, and 100G are similar to the SRAM cells 100, 100A, 100B, and 100C discussed above, respectively, except that the non-functional nanostructures 310′ of the pull-up transistors PU-1 and PU-2 are omitted. For simplicity, similar features and relationships discussed above in the SRAM cells 100, 100A, 100B, and 100C are not repeated in the SRAM cells 100D, 100E, 100F, and 100G. Referring back to FIGS. 5B and 5D, the pull-up transistors PU-1 and PU-2 in the SRAM cells 100, 100A, 100B, and 100C include the non-functional nanostructures 310′ under the nanostructures 310, as discussed. As shown in FIGS. 9A, 9C, 10B, 11B and 12B, no non-functional nanostructures 310′ are under the nanostructures 310, and the gate structures 304 are between the bottommost surfaces of the nanostructures 310 and the substrate 302 in the Z-direction, in accordance with some embodiments.

Referring back to FIG. 5D, the non-functional nanostructures 310′ are between the isolation layers 311 in the Y-direction, as discussed. As shown in FIGS. 9A, 9C, 10B, 11B and 12B, no non-functional nanostructures 310′ are between the isolation layers 311, and the gate structures 304 and the inner spacers 322 are between the isolation layers 311 in the Y-direction, in accordance with some embodiments. More specifically, an entirety of sidewalls of the isolation layers 311 is in contact with the inner spacers 322 and the substrate 302 in the Y-direction. Furthermore, as shown in FIGS. 9C, 10B, 11B and 12B, in the pull-up transistors PU-1 and PU-2, a thickness of portions of the inner spacers 322 vertically between (the bottommost surfaces of) the nanostructures 310 and the substrate 302 is greater than a thickness of other portions of the inner spacers 322 vertically between the nanostructures 310, in accordance with some embodiments.

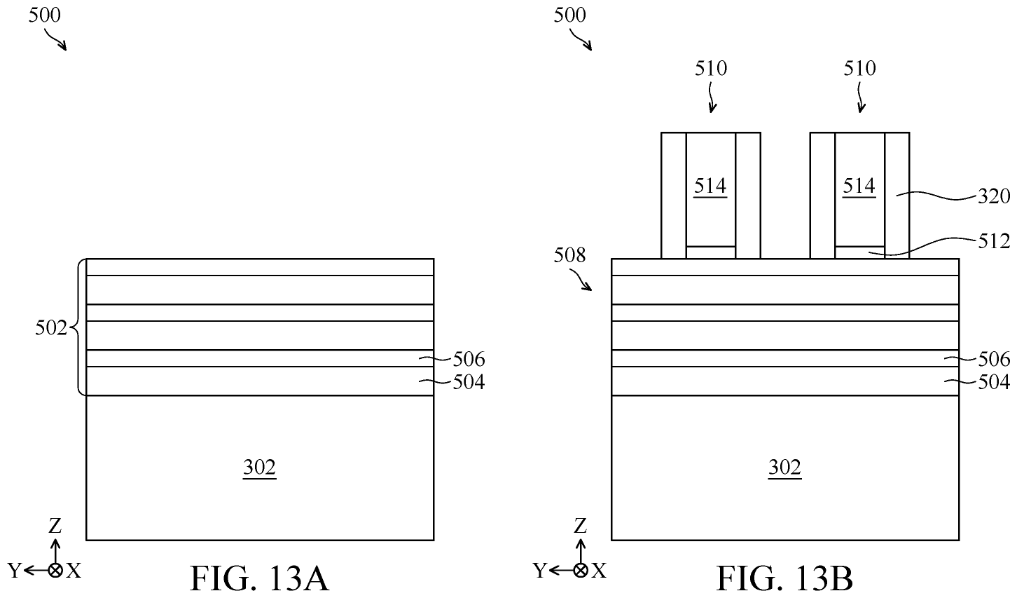

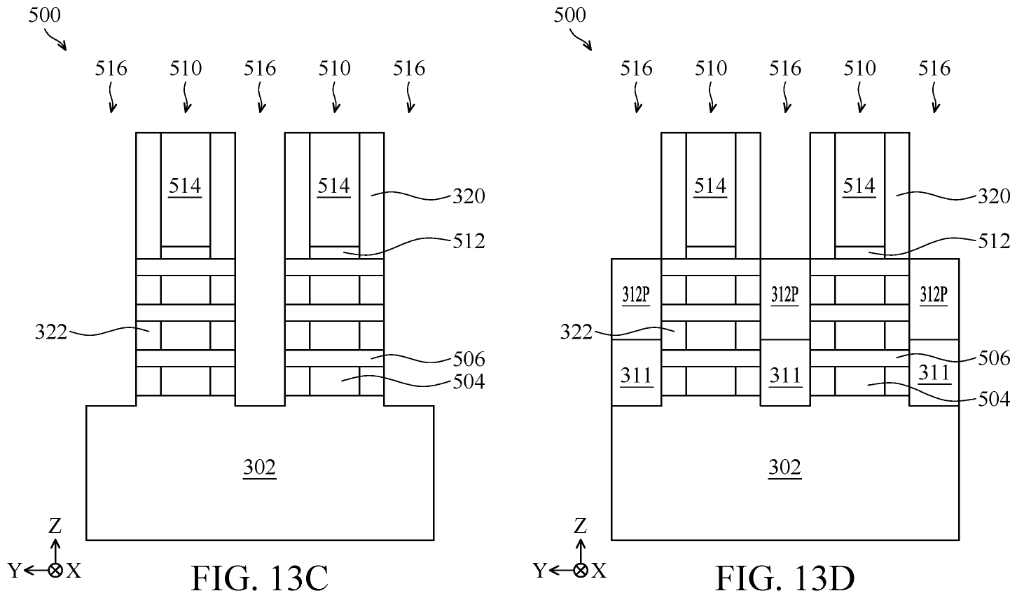

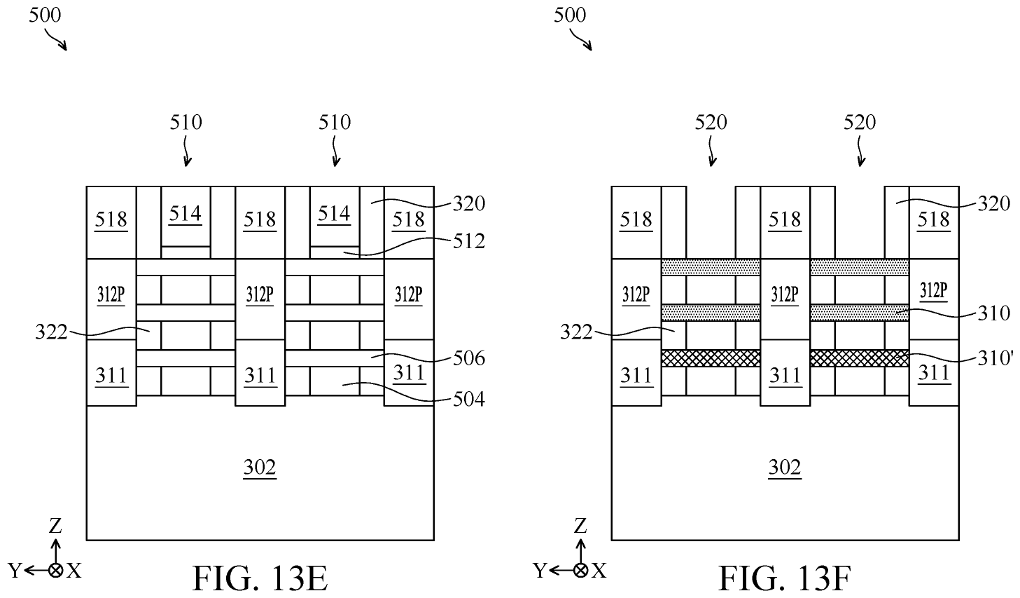

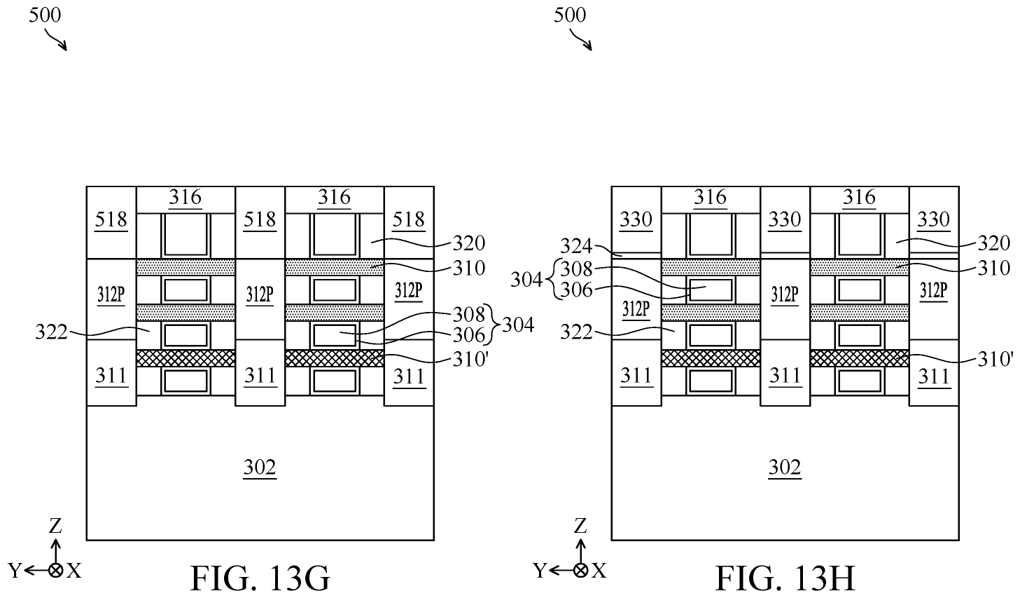

FIGS. 13A to 13H are cross-sectional views of a device 500 at various fabrication stages, which show exemplary fabrication of transistors with non-functional nanostructures for the pull-up transistors PU-1 and PU-2 discussed above, in accordance with some embodiments of the present disclosure. Referring to FIG. 13A, a stack 502 is formed over the substrate 302. In some embodiments, the substrate 302 may include one or more well regions, such as n-type well regions (e.g., the n-type well NW discussed above) doped with an n-type dopant (i.e., phosphorus (P) or arsenic (As)) or p-type well regions (e.g., the p-type well PW discussed above) doped with a p-type dopant (i.e., boron (B)), for forming different types of devices. The doping the n-type wells and the p-type wells may be formed using ion implantation or thermal diffusion.

The stack 502 includes semiconductor layers 504 and 506, and the semiconductor layers 504 and 506 are alternatingly stacked in the Z-direction. The semiconductor layers 504 and the semiconductor layers 506 may have different semiconductor compositions. In some embodiments, semiconductor layers 504 are formed of silicon germanium (SiGe) and the semiconductor layers 506 are formed of silicon (Si). In these embodiments, the additional germanium content in the semiconductor layers 504 allow selective removal or recess of the semiconductor layers 504 without substantial damages to the semiconductor layers 506, so that the semiconductor layers 504 are also referred to as sacrificial layers. In some embodiments, the semiconductor layers 504 and 506 are epitaxially grown over (on) the substrate 302 using a deposition technique such as epitaxial growth, vapor-phase epitaxy (VPE), molecular beam epitaxy (MBE), although other deposition processes, such as chemical vapor deposition (CVD), low pressure CVD (LPCVD), atomic layer deposition (ALD), ultrahigh vacuum CVD (UHVCVD), reduced pressure CVD (RPCVD), a combination thereof, or the like, may also be utilized. The semiconductor layers 504 and the semiconductor layers 506 are deposited alternatingly, one-after-another, to form the stack 502.

It should be noted that three (3) layers of the semiconductor layers 504 and three (3) layers of the semiconductor layers 506 are alternately and vertically arranged (or stacked) as shown in FIG. 13A, which are for illustrative purposes only and not intended to be limiting beyond what is specifically recited in the claims. For the pull-up transistors PU-1 and PU-2 discussed above, the top two semiconductor layers 506 are subsequently formed into the nanostructures 310 and the bottommost semiconductor layer 506 is subsequently formed into the non-functional nanostructures 310′ In some embodiments, the bottommost semiconductor layer 506 is replaced with a thicker semiconductor layer 506 formed between the top two semiconductor layers 506 and the substrate 302 for fabricating the pull-up transistors PU-1 and PU-2 without the non-functional nanostructures 310′ discussed above.

Referring to FIG. 13B, after the formation of the stack 502, the stack 502 is then patterned to form fins 508 over the substrate 102. Although not shown in FIG. 13B, after the formation of the fins 508, the isolation feature 314 discussed is then formed over the substrate 302 and between the fins 508.

Still referring to FIG. 13B, dummy gate structures 510 are formed over the fins 508. In some embodiments, to form the dummy gate structures 510, a dummy interfacial material for dummy interfacial layers 512 is first formed over fins 508. In some embodiments, the dummy interfacial layer 512 may include, for example, a dielectric material such as a nitride (e.g., silicon nitride, silicon oxynitride), a carbide (e.g., silicon carbide), an oxide (e.g., silicon oxide), or some other suitable material. Then, in some embodiments, a dummy gate material for dummy gate electrodes 514 is formed over the dummy interfacial material. The dummy gate material may include a conductive material selected from a group comprising of polysilicon, W, Al, Cu, AlCu, Ti, TiAlN, TaC, TaCN, TaSiN, Mn, Zr, TiN, Ta, TaN, Co, Ni, and/or a combination thereof. The dummy gate material and/or the dummy interfacial material may be formed by way of a thermal oxidation process and/or a deposition process (e.g., physical vapor deposition (PVD), CVD, PECVD, and ALD).

After the formation of the dummy interfacial material and the dummy gate material, one or more etching processes may be performed to pattern the dummy gate material for the dummy gate electrodes 514 and the dummy interfacial material for the dummy interfacial layers 512, thereby forming the dummy gate structures 510 each having the dummy interfacial layer 512 and the dummy gate electrode 514. The dummy interfacial layers 512 may also be referred to as dummy gate dielectrics. The dummy gate structures 510 may undergo a gate replacement process through subsequent processing to form metal gates, such as a high-k metal gate, as discussed in greater detail below.

Still referring to FIG. 13B, after the formation of the dummy gate structures 510, gate spacers 320 are formed on sidewalls of the dummy gate structures 510 and over the top surfaces of the fins 508. More specifically, the gate spacers 320 are formed on opposite sidewalls of the dummy gate structures 510. In some embodiments, the gate spacers 320 may be formed by conformally depositing a spacer layer (containing the dielectric material) over the fins 508 and dummy gate structures 510, followed by an anisotropic etching process to remove top portions of the spacer layer from the top surfaces of the fins 508 and dummy gate structures 510. After the etching process, portions of the spacer layer on the sidewall surfaces of the fins 508 and the dummy gate structures 510 substantially remain and become the gate spacers 320. In some embodiments, the anisotropic etching process is a dry (e.g., plasma) etching process. Additionally or alternatively, the formation of the gate spacers 320 may also involve chemical oxidation, thermal oxidation, ALD, CVD, and/or other suitable methods. The gate spacers 320 may also be interchangeably referred to as top spacers

Referring to FIG. 13C, the fins 508 are recessed to form source/drain trenches 516 in the fins 508 (or passing through the semiconductor layers 504 and 506). Specifically, the source/drain trenches 516 may be formed by performing one or more etching processes to remove portions of the semiconductor layers 504, the semiconductor layers 506, and the substrate 302 that do not vertically overlap or be covered by the dummy gate structures 510 and the gate spacers 320. In some embodiments, a single etchant may be used to remove the semiconductor layers 504, the semiconductor layers 506, and the substrate 302, whereas in other embodiments, multiple etchants may be used to perform the etching process. As shown in FIG. 13C, portions of the substrate 302 are etched, so that bottom surfaces of the source/drain trenches 516 are lower than the topmost surfaces of the substrate 302.

Still referring to FIG. 13C, the inner spacers 322 are formed under the gate spacers 320 and between the semiconductor layers 506 as well as between the semiconductor layers 506 and the substrate 302. In formation of the inner spacers 322, side portions of the semiconductor layers 504 are removed via a selective etching process. Specifically, the selective etching process is performed that selectively etches the side portions of the semiconductor layers 504 under the gate spacers 320 through the source/drain trenches 516, with minimal (or no) etching of semiconductor layers 506, such that gaps are formed between the semiconductor layers 506 as well as between the semiconductor layers 506 and the substrate 302. The etching process is configured to laterally etch (e.g., in the first direction) the semiconductor layers 504 below the gate spacers 320. The selective etching process is a dry etching process, a wet etching process, another suitable etching process, or a combination thereof.

Still referring to FIG. 13C, the inner spacers 322 are then formed to fill the gaps. In some embodiments, sidewalls of the inner spacers 322 are aligned to sidewalls of the gate spacers 320 and the semiconductor layers 506, as shown in FIG. 13C. In order to form the inner spacers 322, a deposition process forms a spacer layer into the source/drain trenches 516 and the gaps, such as CVD, PVD, ALD, HDPCVD, MOCVD, RPCVD, PECVD, LPCVD, ALCVD, APCVD, other suitable methods, or combinations thereof. The spacer layer partially (and, in some embodiments, completely) fills the source/drain trenches 516. The deposition process is configured to ensure that the spacer layer fills the gaps between the semiconductor layers 506 as well as between the semiconductor layer 506 and the substrate 302 under the gate spacers 320. An etching process is then performed that selectively etches the spacer layer to form inner spacers 322 (as shown in FIG. 13C) with minimal (to no) etching of the semiconductor layer 506, the substrate 302, the dummy gate structures 510, and the gate spacers 320.

Referring to FIG. 13D, the isolation layers 311 and the source/drain features 312P over the isolation layers 311 are formed in the source/drain trenches 516. The isolation layers 311 are in contact with the bottommost semiconductor layers 506 (subsequent formed into the non-functional nanostructures 310′) and the source/drain features 312P are in contact with the top two semiconductor layers 506 (subsequent formed into the nanostructures 310). The bottommost semiconductor layers 506 (the non-functional nanostructures 310′) is turned off, blocked, and disabled by the isolation layers 311, as discussed above. The source/drain features 312P are electrically connected to the top two semiconductor layers 506. One or more epitaxy processes may be employed to grow the source/drain features 312P. Epitaxy processes can implement CVD deposition techniques (for example, vapor-phase epitaxy (VPE), UHVCVD, LPCVD, and/or PECVD), molecular beam epitaxy, other suitable SEG processes, or combinations thereof. One or more annealing processes may be performed to activate the dopants in the source/drain features 312P. The annealing processes may include rapid thermal annealing (RTA) and/or laser annealing processes.

Referring to FIG. 13E, an interlayer dielectric (ILD) layer 518 is formed to fill the space between the gate spacers 320. The ILD layer 518 may comprise tetraethylorthosilicate (TEOS) formed oxide, un-doped silicate glass, or doped silicon oxide such as borophosphosilicate glass (BPSG), fluoride-doped silica glass (FSG), phosphosilicate glass (PSG), boron doped silicon glass (BSG), a low-k dielectric material, other suitable dielectric material, or combinations thereof. The ILD layer 518 may be formed by PECVD (plasma enhanced CVD), FCVD (flowable CVD), or other suitable methods. Subsequent to the formation of the ILD layer 518, a CMP process and/or other planarization process is performed on the ILD layer 518 until the top surfaces of the dummy gate structures 510 are exposed.

In some embodiments, before the formation of the ILD layer 518, a contact etch stop layer (CESL) may be conformally formed on the sidewalls of the gate spacers 320 and over the top surfaces of the source/drain features 312P. The ILD layer 518 is then formed over and between the CESL to fill the space between the CESL. The CESL includes a material that is different than ILD layer 518. The CESL may include La₂O₃, Al₂O₃, SiOCN, SiOC, SiCN, SiO₂, SiC, ZnO, ZrN, Zr₂Al₃O₉, TiO₂, TaO₂, ZrO₂, HfO₂, Si₃N₄, Y₂O₃, AlON, TaCN, ZrSi, or other suitable material(s); and may be formed by CVD, PVD, ALD, or other suitable methods.

Referring to FIG. 13F, the dummy gate structures 510 are selectively removed through any suitable lithography and etching processes. In some embodiments, the lithography process may include forming a photoresist layer (resist), exposing the resist to a pattern, performing a post-exposure bake process, and developing the resist to form a masking element, which exposes a region including the dummy gate structures 510. Then, the dummy gate structures 510 are selectively etched through the masking element. Etch selectivity may be achieved by selecting the appropriate etching chemicals, and the dummy gate structures 510 may be removed without substantially affecting the gate spacers 320, the inner spacers 322, and the substrate 302. The removal of the dummy gate structures 510 creates gate trenches 520. The gate trenches 520 expose the top surfaces of the topmost semiconductor layers 506 underlies the dummy gate structures 510.

Still referring to FIG. 13F, the semiconductor layers 504 are selectively removed through the gate trenches 520, using a wet or dry etching process for example, so that the semiconductor layers 506 are exposed in the gate trenches 520 to form the nanostructures 310 and the non-functional nanostructures 310′. Such a process may also be referred to as a wire release process, a nanowire release process, a nanosheet release process, a nanowire formation process, a nanosheet formation process, or a wire formation process. In some embodiments, the removal of the semiconductor layers 504 causes the exposed semiconductor layers 506 (the nanostructures 310 and the non-functional nanostructures 310′) to be spaced apart from each other in the vertical direction (e.g., in the third direction). The exposed semiconductor layers 506 extend longitudinally in the horizontal direction (e.g., in the Y-direction), and each connects one source/drain feature 312P to another source/drain feature 312P.

Referring to FIG. 13G, the gate structures 304 discussed above are formed in the gate trenches 520. The gate structures 304 each includes the gate dielectric layer 306 and the gate electrode 308 over the gate dielectric layer 306, as discussed above. In some embodiments, the gate dielectric layers 1102 are formed to wrap around wrap around each of the nanostructures 310 and the non-functional nanostructures 310′. Additionally, the gate dielectric layers 306 are also formed on sidewalls of the inner spacers 322 and the gate spacers 320.

The gate electrodes 308 are then formed to fill the remaining spaces of the gate trenches 520, and over the gate dielectric layers 306 in such a way that the gate electrodes 308 each wraps around the nanostructures 310, the non-functional nanostructures 310′, the gate dielectric layer 306, and the interfacial layers (if present). The gate electrodes 308, the gate dielectric layers 306, and the interfacial layers (if present) may be collectively called as the gate structures 304 wrapping around the nanostructures 310 and the non-functional nanostructures 310′, as discussed above. After the formation of the gate structures 304, portions of the gate structures 304 and the gate spacers 320 are recessed, and the gate top dielectric layers 316 discussed above are formed over the gate structures 304 and the gate spacers 320.

Referring to FIG. 13H, the source/drain contacts 330 discussed above are formed in the ILD layer 518. As shown in FIG. 13H, the source/drain contacts 330 are electrically coupled to the source/drain feature 312P. In some embodiments, additional features are formed between the source/drain features 312P and the source/drain contacts 330, such as the silicide features 324 discussed above. As such, the device 500 is completely formed to have transistors with the non-functional nanostructures 310′ for presenting the exemplary fabrication of the pull-up transistors PU-1 and PU-2 discussed above.

The embodiments disclosed herein relate to memory devices, and more particularly to memory devices comprising the SRAM cells having pull-up transistors with less active nanostructures (channel layers). Furthermore, the present embodiments provide one or more of the following advantages. The less active nanostructures of the pull-up transistors improve write margin without reducing the SRAM cell size for impacting process margin. Furthermore, the isolation layers under the active nanostructures of the pull-up transistors for blocking the non-functional nanostructures prevents the leakage current o the SRAM cell, thereby improving the performance of the SRAM cell.

Thus, one of the embodiments of the present disclosure describes a memory device that includes a static random-access memory (SRAM) cell over a substrate. The SRAM cell includes a first inverter and a second inverter. The first inverter has a first pull-down transistor and a first pull-up transistor. The second inverter has a second pull-down transistor and a second pull-up transistor. The first inverter and the second inverter are cross-coupled to each other. Each of the first pull-down transistor, the first pull-up transistor, the second pull-down transistor, and the second pull-up transistor includes active channel layers vertically stacked. A number of the active channel layers of the first pull-up transistor is less than a number of the active channel layers of the first pull-down transistor or the second pull-down transistor.

In some embodiments, each of the first pull-down transistor, the first pull-up transistor, the second pull-down transistor, and the second pull-up transistor further includes source/drain features on opposite sides of the active channel layers. Bottom surfaces of the source/drain features of the first pull-down transistor and the second pull-down transistor are lower than bottom surfaces of the source/drain features of the first pull-up transistor and the second pull-up transistor.

In some embodiments, the bottom surfaces of the source/drain features of the first pull-down transistor and the second pull-down transistor are in contact with the substrate. The bottom surfaces of the source/drain features of the first pull-up transistor and the second pull-up transistor are separated from the substrate.

In some embodiments, each of the first pull-down transistor, the first pull-up transistor, the second pull-down transistor, and the second pull-up transistor further includes isolation layers vertically sandwiched between the source/drain features and the substrate.

In some embodiments, a thickness of the isolation layers of the first pull-up transistor and the second pull-up transistor is greater than a thickness of the isolation layers of the first pull-down transistor and the second pull-down transistor.

In some embodiments, each of the first pull-up transistor and the second pull-down transistor further includes epitaxial layers vertically sandwiched between the isolation layers and the substrate.

In some embodiments, a thickness of the isolation layers of the first pull-up transistor and the second pull-up transistor is equal to a thickness of the isolation layers of the first pull-down transistor and the second pull-down transistor.

In some embodiments, each of the first pull-down transistor, the first pull-up transistor, the second pull-down transistor, and the second pull-up transistor further includes air gaps separating the source/drain features from the isolation layers.

In some embodiments, each of the first pull-up transistor and the second pull-down transistor further includes an inactive channel layer under the active channel layers.

In some embodiments, top surfaces of the isolation layers of the first pull-up transistor and the second pull-up transistor are higher than top surfaces of the inactive channel layers.

In another of the embodiments, discussed is a memory device including a static random-access memory (SRAM) cell over a substrate. The SRAM cell includes a first pull-down transistor and a first pull-up transistor sharing a first gate structure extending in an X-direction. The SRAM cell further includes a second pull-down transistor and a second pull-up transistor sharing a second gate structure extending in the X-direction. Each of the first pull-down transistor, the first pull-up transistor, the second pull-down transistor, and the second pull-up transistor includes nanostructures vertically stacked in a Z-direction and source/drain features attached to the nanostructures in a Y-direction. A distance from a topmost surface to a bottommost surface of the nanostructures of the first pull-up transistor is less than a distance from a topmost surface to a bottommost surface of the nanostructures of the first pull-down transistor or the second pull-down transistor.

In some embodiments, bottom surfaces of the source/drain features of the first pull-down transistor and the second pull-down transistor are lower than bottommost surfaces of the first gate structure and the second gate structure.

In some embodiments, the memory device further includes isolation layers on opposite sides of the first gate structure and the second gate structure. The source/drain features are separated from the substrate by the isolation layers in the Z-direction.

In some embodiments, the source/drain features are separated from the isolation layers in the Z-direction.

In some embodiments, each of the first pull-up transistor and the second pull-up transistor further includes a non-functional nanostructure between a bottommost surface of the nanostructures and the substrate in the Z-direction.

In some embodiments, each of the first pull-up transistor and the second pull-up transistor further includes epitaxial layers over the substrate in the Z-direction. The isolation layers are separated from the substrate by the epitaxial layers.

In yet another of the embodiments, discussed is a memory device that includes a static random-access memory (SRAM) cell. The SRAM cell includes a first pass-gate transistor, a second pass-gate transistor, a first pull-down transistor, a second pull-down transistor, a first pull-up transistor, and a second pull-up transistor. Each of the first pass-gate transistor, the second pass-gate transistor, the first pull-down transistor, the second pull-down transistor, the first pull-up transistor, and the second pull-up transistor includes active channel layers vertically stacked in a Z-direction, source/drain features on opposite sides of the active channel layers in a Y-direction, and isolation layers under the source/drain features in the Z-direction. A number of the active channel layers of the first pull-up transistor is less than a number of the active channel layers of the first pull-down transistor, the second pull-down transistor, the first pass-gate transistor, or the second pass-gate transistor.

In some embodiments, each of the first pass-gate transistor, the second pass-gate transistor, the first pull-down transistor, the second pull-down transistor, the first pull-up transistor, and the second pull-up transistor further includes isolation layers over a substrate. The source/drain features are separated from the substrate by the isolation layers in the Z-direction.

In some embodiments, each of the first pass-gate transistor, the second pass-gate transistor, the first pull-down transistor, the second pull-down transistor, the first pull-up transistor, and the second pull-up transistor further includes an inactive channel between the isolation layers in the Y-direction.

In some embodiments, each of the first pass-gate transistor, the second pass-gate transistor, the first pull-down transistor, the second pull-down transistor, the first pull-up transistor, and the second pull-up transistor further includes air gaps between the source/drain features and the isolation layers in the Z-direction.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A memory device, comprising:
a static random-access memory (SRAM) cell over a substrate, wherein the SRAM cell comprises:
a first inverter having a first pull-down transistor and a first pull-up transistor; and
a second inverter having a second pull-down transistor and a second pull-up transistor,
wherein the first inverter and the second inverter are cross-coupled to each other,
wherein each of the first pull-down transistor, the first pull-up transistor, the second pull-down transistor, and the second pull-up transistor comprises:
active channel layers vertically stacked,
wherein a number of the active channel layers of the first pull-up transistor is less than a number of the active channel layers of the first pull-down transistor or the second pull-down transistor.

2. The memory device of claim 1, wherein each of the first pull-down transistor, the first pull-up transistor, the second pull-down transistor, and the second pull-up transistor further comprises:
source/drain features on opposite sides of the active channel layers,
wherein bottom surfaces of the source/drain features of the first pull-down transistor and the second pull-down transistor are lower than bottom surfaces of the source/drain features of the first pull-up transistor and the second pull-up transistor.

3. The memory device of claim 2, wherein the bottom surfaces of the source/drain features of the first pull-down transistor and the second pull-down transistor are in contact with the substrate, and
wherein the bottom surfaces of the source/drain features of the first pull-up transistor and the second pull-up transistor are separated from the substrate.

4. The memory device of claim 2, wherein each of the first pull-down transistor, the first pull-up transistor, the second pull-down transistor, and the second pull-up transistor further comprises:
isolation layers vertically sandwiched between the source/drain features and the substrate.

5. The memory device of claim 4, wherein a thickness of the isolation layers of the first pull-up transistor and the second pull-up transistor is greater than a thickness of the isolation layers of the first pull-down transistor and the second pull-down transistor.

6. The memory device of claim 4, wherein each of the first pull-up transistor and the second pull-down transistor further comprises:
epitaxial layers vertically sandwiched between the isolation layers and the substrate.

7. The memory device of claim 6, wherein a thickness of the isolation layers of the first pull-up transistor and the second pull-up transistor is equal to a thickness of the isolation layers of the first pull-down transistor and the second pull-down transistor.

8. The memory device of claim 4, wherein each of the first pull-down transistor, the first pull-up transistor, the second pull-down transistor, and the second pull-up transistor further comprises:
air gaps separating the source/drain features from the isolation layers.

9. The memory device of claim 4, wherein each of the first pull-up transistor and the second pull-down transistor further comprises:
an inactive channel layer under the active channel layers.

10. The memory device of claim 9, wherein top surfaces of the isolation layers of the first pull-up transistor and the second pull-up transistor are higher than top surfaces of the inactive channel layers.

11. A memory device, comprising:
a static random-access memory (SRAM) cell over a substrate, wherein the SRAM cell comprises:
a first pull-down transistor and a first pull-up transistor sharing a first gate structure extending in an X-direction; and
a second pull-down transistor and a second pull-up transistor sharing a second gate structure extending in the X-direction,
wherein each of the first pull-down transistor, the first pull-up transistor, the second pull-down transistor, and the second pull-up transistor comprises:
nanostructures vertically stacked in a Z-direction; and
source/drain features attached to the nanostructures in a Y-direction,
wherein a distance from a topmost surface to a bottommost surface of the nanostructures of the first pull-up transistor is less than a distance from a topmost surface to a bottommost surface of the nanostructures of the first pull-down transistor or the second pull-down transistor.

12. The memory device of claim 11, wherein bottom surfaces of the source/drain features of the first pull-down transistor and the second pull-down transistor are lower than bottommost surfaces of the first gate structure and the second gate structure.

13. The memory device of claim 11, further comprising:
isolation layers on opposite sides of the first gate structure and the second gate structure, wherein the source/drain features are separated from the substrate by the isolation layers in the Z-direction.

14. The memory device of claim 13, wherein the source/drain features are separated from the isolation layers in the Z-direction.

15. The memory device of claim 13, wherein each of the first pull-up transistor and the second pull-up transistor further comprises:
a non-functional nanostructure between a bottommost surface of the nanostructures and the substrate in the Z-direction.

16. The memory device of claim 15, wherein each of the first pull-up transistor and the second pull-up transistor further comprises:
epitaxial layers over the substrate in the Z-direction, wherein the isolation layers are separated from the substrate by the epitaxial layers.

17. A memory device, comprising:
a static random-access memory (SRAM) cell comprising a first pass-gate transistor, a second pass-gate transistor, a first pull-down transistor, a second pull-down transistor, a first pull-up transistor, and a second pull-up transistor, wherein each of the first pass-gate transistor, the second pass-gate transistor, the first pull-down transistor, the second pull-down transistor, the first pull-up transistor, and the second pull-up transistor comprises:
active channel layers vertically stacked in a Z-direction;
source/drain features on opposite sides of the active channel layers in a Y-direction; and
isolation layers under the source/drain features in the Z-direction,
wherein a number of the active channel layers of the first pull-up transistor is less than a number of the active channel layers of the first pull-down transistor, the second pull-down transistor, the first pass-gate transistor, or the second pass-gate transistor.

18. The memory device of claim 17, wherein each of the first pass-gate transistor, the second pass-gate transistor, the first pull-down transistor, the second pull-down transistor, the first pull-up transistor, and the second pull-up transistor further comprises:
isolation layers over a substrate, wherein the source/drain features are separated from the substrate by the isolation layers in the Z-direction.

19. The memory device of claim 18, wherein each of the first pass-gate transistor, the second pass-gate transistor, the first pull-down transistor, the second pull-down transistor, the first pull-up transistor, and the second pull-up transistor further comprises:
an inactive channel between the isolation layers in the Y-direction.

20. The memory device of claim 19, wherein each of the first pass-gate transistor, the second pass-gate transistor, the first pull-down transistor, the second pull-down transistor, the first pull-up transistor, and the second pull-up transistor further comprises:
air gaps between the source/drain features and the isolation layers in the Z-direction.
